(19) United States
(12) Patent Application Publication
(10) Pub. No.: US 2024/0222937 A1
(43) Pub. Date: Jul. 4, 2024

(54) MULTILAYER STRUCTURES MADE OF INDIUM PHOSPHIDE OR GALLIUM ARSENIDE

(71) Applicant: Yale University, New Haven, CT (US)

(72) Inventors: Jung Han, New Haven, CT (US); Jin-Ho Kang, Hamden, CT (US); Bingjun Li, New Haven, CT (US)

(21) Appl. No.: 18/558,888

(22) PCT Filed: May 3, 2022
(86) PCT No.: PCT/US2022/027391

§ 371 Date: Nov. 3, 2023

Related U.S. Application Data
(60) Provisional application No. 63/183,337, filed on May 3, 2021.

(51) Int. Cl. H01S 5/183

(52) U.S. Cl. CPC H01S 5/18361; H01S 2302/00

(57) ABSTRACT

Multilayer structures containing porosified or electropolished layers of indium phosphide or gallium arsenide are described. Further disclosed are methods for preparing and using such multilayer structures, for example, in vertical cavity surface emitting lasers (VCSELs).

### CROSS-REFERENCE TO RELATED APPLICATION

This application claims priority to and benefit of U.S. Provisional Application No. 63/183,337, filed May 3, 2021, which is hereby incorporated herein by reference in its entirety.

### FIELD OF THE INVENTION

This invention is in the field of multilayer structures, including indium phosphide or gallium arsenide structures, the structures containing porous or etched layers therein, which can be used in electronic applications, such as photonic devices.

### BACKGROUND OF THE INVENTION

Semiconductor laser diodes have found many applications in modern society. In the world of laser diodes, vertical cavity surface emitting lasers (VCSELs) are known to be superior to the edge-emitting lasers (EEL) in terms of cost, manufacturability, flexibility, beam quality, and potential integration. So far EEL is commercially available from the wavelength of approximately 400 nm (violet) to about 2,000 nm (near-infrared).

VCSELs are only commercially available from ˜700 nm (red) to 1 μm. Nevertheless, the wavelength range from 1,200 nm to 1,600 nm is an important one since this is traditionally the range used in silica fibers for long-haul single-mode telecommunication. 1,550 nm is also important as a window for atmospheric wireless transmission of signals and energies.

VCSELs emitting at 1,200 to 1,600 nm (or 1.2 to 1.6 μm) are typically prepared epitaxially on indium phosphide (InP) substrates. For at least the past 20 years, the pursuit of the long-wavelength VCSELs has followed one of three approaches, all with the active (light emitting) regions prepared on InP substrates. However, the methods for forming the vertical cavity, and specifically the formation of the n-side reflective mirror, differs dramatically. None of the 3 approaches have achieved mainstream, large-scale production in spite of the compelling market demand. The three representative approaches are as follows:
(1) InGaAs/InAlAs epitaxial distributed Bragg reflector (DBR) on InP (Ortsiefer, M., et al. (2005). 2.5-mW single-mode operation of 1.55-μm buried tunnel junction VCSELs. IEEE photonics technology letters, 17(8), 1596-1598): This approach was attempted since the late 1990s. The DBRs were formed by the InGaAs and InAlAs alloys, which are lattice matched to InP substrates. These two lattice-matched layers, however, have a very limited contrast in optical refractive indices (˜0.25), therefore a very large number of quarter-wavelength layers are needed. InGaAs and InAlAs also both have low thermal conductivities (˜2 W/m-k), making heat dissipation very difficult. VCSELs were made with a hybrid mirror with good thermal conductivities and flip-chip mounted. Nevertheless, the epitaxial process and fabrication combined make this process difficult and to our knowledge it has not been pursued after 2005.
(2) Al(Ga)As/GaAs epitaxial distributed Bragg reflector (DBR) wafer-fused with InP-based active region (Caliman, A. et al. (2011). 8 mW fundamental mode output of wafer-fused VCSELs emitting in the 1550-nm band. Optics express, 19(18), 16996-17001): This approach combined the Al(Ga)As/GaAs epitaxial DBR technology on GaAs substrates with an InGaAs active region and p-n layers on InP by wafer fusion. This process, however, required multiple regrowths, chemo-mechanical-polishing (CMP) with the need for precise thickness control in order to precisely control the cavity modes and modal gains. Two spacer regions were required for precise, reproducible, and uniform control that often caused reduced device yields.
(3) Hybrid dielectric back mirror combined with dielectric top mirror (Spiga, S., et al. (2016). Single-mode high-speed 1.5-μm VCSELs. Journal of Lightwave Tech, 35(4), 727-733): Another approach used since early 2000s has been to sandwich the epitaxial InGaAs active region (prepared on InP substrates) with a top dielectric DBR mirror, followed by the removal of the InP substrates, followed by depositing the hybrid dielectric back mirror and then encapsulating the construct in a thermally conductive gold/BCB assembly. This approach results in mirrors of very high index contrast with very small penetration depths of the vertical lasing modes and short cavity and small mode volume for a high modulation bandwidth can be achieved. However, these all-dielectric VCSELs cannot be manufactured easily with good control or high yield, causing the unit cost to be very high, where many of the inherent benefits with monolithic VCSELs cease to exist.

Notwithstanding the above methods, fabrication of VCSELs on InP substrates remains very challenging. Therefore, to date, technology space using long-wavelength VCSELs for defense and commercial applications, amongst others, remains essentially un-addressed.

Thus, there is a need for novel semiconductor structures, which can be used as mirrors, and can be fabricated via simplified methods, and can be used to fabricate VCSELs of desired wavelengths.

Therefore, it is an object of the invention to provide such structures which address and overcome the issues known to-date in the manufacture of devices, such as VCSELs.

It is yet another object of the invention to provide novel methods for preparing such structures.

It is still a further object of the invention to provide methods of using the structures described, such as for use in VCSELS.

### SUMMARY OF THE INVENTION

Multilayer structures containing indium phosphide (InP) or gallium arsenide (GaAs) layers which are porous or electropolished within the structure are described herein.

In one instance, a non-limiting exemplary of the multilayer structure contains:
a plurality of undoped or low doped (see below) indium phosphide or gallium arsenide layers optionally present on a single-crystalline substrate formed of indium phosphide, gallium arsenide, sapphire, silicon, or silicon carbide,
where the multilayer comprises at least one layer of an n-doped indium phosphide or gallium arsenide which is present between at least two layers of undoped or low doped indium phosphide or gallium arsenide and the n-doped indium phosphide or gallium arsenide contains at least a region or portion that is porous or electropolished due to electrochemical etching, and
where the at least one layer of n-doped indium phosphide or gallium arsenide, when porous, contains a plurality of pores within the n-doped indium phosphide or gallium arsenide layer that are confined by adjacent undoped or low n-doped indium phosphide or gallium arsenide layers that are non-porous or substantially non-porous.

Selective incorporation of a low index material, such as air, into selected regions of the multilayer structures by electrochemically etching has the effect of lowering the refractive index, as compared to the bulk InP or GaAs. Thus, it is possible to tune the refractive index of the porosified regions within the multilayer structure selectively.

Selective incorporation of air by porosification or electropolishing into selected regions of doped layers in a multilayer structure by electrochemical etching can affect electrical properties, as compared to the bulk (non-porous) equivalent InP or GaAs. Thus, it is possible to tune the electrical properties of the porosified regions within the multilayer structure selectively.

Selective incorporation of air by porosification or electropolishing into selected regions of doped layers in a multilayer structure by electrochemical etching can affect thermal properties, as compared to the bulk (non-porous) equivalent InP or GaAs.

In one non-limiting example, a method of forming a multilayer structure, the method includes the steps of:
(a) forming a first layer of undoped or low doped indium phosphide or gallium arsenide above an optional substrate layer;
(b) depositing a second layer of an n-doped indium phosphide or gallium arsenide over the first layer;
(c) depositing a third layer of undoped or low doped indium phosphide or gallium arsenide above the second layer;
(d) optionally repeating steps (b) and (c) to form additional alternating layers the n-doped indium phosphide or gallium arsenide and the undoped or low doped indium phosphide or gallium arsenide;
(e) depositing a capping layer over the entire multilayer structure; (f) removing at least a portion of the capping layer to selectively expose at least one sidewall of the multilayer structure; and
(g) electrochemically (EC) etching n-doped indium phosphide or gallium arsenide layers in the presence of an electrolyte and under an applied bias voltage to selectively porosify or electropolish at least a portion of the n-doped indium phosphide or gallium arsenide layers present;
where the n-doped indium phosphide or gallium arsenide layers, when porosified, comprise a plurality of pores within the n-doped indium phosphide or gallium arsenide layer that are confined by adjacent undoped or low n-doped indium phosphide or gallium arsenide layers that are non-porous or substantially non-porous.

The multilayer structures can be used in various applications including electronic, photonic, and optoelectronic applications. Applications for such multilayer structures include, more specifically, fiber-based communications, free-space communications, LiDAR, sensing and range-finding, night vision, and chemical sensing, among others. In particular, the multilayer structures can be used to provide high performance VCSELs with excellent optical and electrical performance, as compared to previously reported VCSELs. VCSELs have many advantages compared to more commonly used edge emitting laser diodes (EELDs), such as superior beam quality, compact form factor, low operating power, cost-effective wafer-level testing, higher yield and lower cost in manufacturing. VCSELs, in general, find important applications in various fields including information processing, micro-display, pico-projection, laser headlamps, high-resolution printing, biophotonics, spectroscopic probing, and atomic clocks.

### BRIEF DESCRIPTION OF THE DRAWINGS

FIG. 1 shows a non-limiting example of a process of electrochemically etching a multilayer structure having alternating n-doped and undoped layers of indium phosphide. When the initial multilayer structure (first structure) is subjected to an electrochemical etching process, (1) selective porosification of n-doped layers occurs (top arrow direction; porosity denoted by formation of nanoporosity in doped layers having air holes therein); or, (2) complete removal of the n-doped layer material (i.e., selective electropolishing) of n-doped layers occurs (bottom arrow direction; air channels formed).

FIG. 2 shows a non-limiting representation of an electrochemically etched multilayer structure having alternating layers of undoped indium phosphide (denoted u-InP) and n-doped indium phosphide (denoted n+InP). The n-doped indium phosphide demonstrate are selectively porosified and the porosification proceeds in a lateral/horizontal direction. The nanopores shown represent air holes.

FIGS. 3A, 3B, and 3C are scanning electron microscopy (SEM) images of an electrochemically etched multilayer structure having alternating layers of undoped indium phosphide (denoted u-InP) and n-doped indium phosphide (denoted n+InP). The n-doped indium phosphide layers were etched in hydrochloric acid at different concentrations and bias voltages, as shown, and demonstrated lateral/horizontal porosification or electropolishing.

FIG. 4A shows an electrochemical etching phase diagram depicting regions where no etching, porosification, and electropolishing occur as a function of doping concentration (y-axis) and applied bias (V) (x-axis), based on experimental electrochemical etching of n-doped indium phosphide (2×10¹⁹ cm⁻³) carried out in oxalic acid (0.05M and 0.3M aq.) at 0.4V, 0.6V, and 1.0V or in hydrochloric acid (0.2M, 1M, and 2M aq.) at 1.1V and 1.7V. FIGS. 4B-4D are scanning electron microscopy (SEM) images of a multilayer structure electrochemically etched in oxalic acid (0.05M and 0.3M aq.) at 0.4V, 0.6V, and 1.0V, where electropolishing of the doped InP layers was observed. FIGS. 4E-4G are scanning electron microscopy (SEM) images of a multilayer structure electrochemically etched in hydrochloric acid (0.2M, 1M, and 2M aq.) at 1.1V and 1.7V, where electropolishing of the doped InP layers was observed.

FIG. 5A shows an electrochemical etching phase diagram depicting regions where no etching, porosification, and electropolishing occur as a function of doping concentration (y-axis) and applied bias (x-axis), based on experimental electrochemical etching of n-doped indium phosphide (2×10¹⁹ cm⁻³) carried out in hydrochloric acid (2M and 3.3M aq.) at 1.2V and 1.5V or KOH (8M aq.) at 0.4V, 0.8V, 1.2V, 1.5V, and 2.0V. FIGS. 5B and 5C are scanning electron microscopy (SEM) images of a multilayer structure electrochemically etched in hydrochloric acid (2M and 3.3M aq.) at 1.2V and 1.5V, where porosification of the doped InP layers was observed. FIGS. 5D, 5E, 5F, 5G, and 5H are scanning electron microscopy (SEM) images of a multilayer structure electrochemically etched in KOH (8M aq.) at 0.4V, 0.8V, 1.2V, 1.5V, and 2.0V, where no etching, porosification, or electropolishing of the doped InP layers was observed dependent on the etching conditions.

FIG. 6 shows an electrochemical etching phase diagram as a function of pore diameter and porosity (y-axis) and electrolyte concentration (x-axis).

FIG. 7 is a graph of the measured reflectance spectrum of an indium phosphide/nanoporous indium phosphide distributed Bragg reflector structure demonstrating near unity reflectance from only six pairs of ¼ λ layers.

FIG. 8 shows an electrochemical etching phase diagram depicting regions where no etching, porosification, and (electro)polishing occur as a function of HCl concentration (%) (y-axis) and applied bias (V) (x-axis).

FIGS. 9A, 9B, and 9C show scanning electron microscopy (SEM) images of a multilayer structure electrochemically etched in 10% HCl at 1.6V, 1.8V, and 2.2V, respectively, where porosification of the doped InP layers (5×10¹⁸ cm⁻³) was observed and where the structure was cleaved along the porosification direction.

FIGS. 10A, 10B, and 10C show scanning electron microscopy (SEM) images of a multilayer structure electrochemically etched in 5% HCl at 1.6V, 1.8V, and 2.0V, respectively, where porosification of the doped InP layers (5×10¹⁸ cm⁻³) was observed and where the structure was cleaved along the porosification direction.

FIGS. 11A, 11B, and 11C show scanning electron microscopy (SEM) images of a multilayer structure electrochemically etched in 5% HCl at 1.6V, 1.8V, and 2.0V, respectively, where porosification of the doped InP layers (5×10¹⁸ cm⁻³) was observed and where the structure was viewed along the porosification direction.

FIG. 12 is a graph of the measured reflectance spectrum of two indium phosphide/nanoporous indium phosphide distributed Bragg reflector structures with low porosity (at 5×10¹⁸ cm⁻³ doping concentration) and high porosity (at 2×10¹⁹ cm⁻³ doping concentration) demonstrating near unity reflectance from only eight and six pairs of ¼ λ layers, respectively.

FIG. 13A shows a non-limiting representation of a vertical cavity structure with a bottom nanoporous InP distributed Bragg reflector (DBR) mirror. FIG. 13B is a graph of a measured (experiment) and simulated reflectance spectrum of the vertical cavity structure with a bottom nanoporous InP distributed Bragg reflector mirror. FIGS. 13C and 13D are graphs of an optical field simulation (λ=1661 nm) of the field intensity (left axis) and refractive index (right axis) as a function of thickness (nm; bottom axis) of the nanoporous InP DBR structure at 0-5000 nm and 0-2000 nm, respectively.

FIG. 14A shows a non-limiting representation of a vertical cavity structure with a bottom nanoporous InP distributed Bragg reflector (DBR) mirror and a top dielectric DBR mirror. FIG. 14B is a graph of measured (experiment) reflectance spectra of the vertical cavity structure with a bottom nanoporous InP distributed Bragg reflector mirror with and without the top dielectric DBR mirror. FIGS. 14C and 14D are graphs of an optical field simulation (λ=1500 nm) of the field intensity (left axis) and refractive index (right axis) as a function of thickness (nm; bottom axis) of the DBR structures present at 0-5000 nm and 0-2000 nm, respectively.

### DETAILED DESCRIPTION OF THE INVENTION

Multilayer structures made of indium phosphide (InP) or gallium arsenide (GaAs) which contain layers which are porous or etched (i.e., electropolished) within the structure are described herein. Methods of manufacturing and using the multilayer structures are also described. For example, the structures can be used as distributed Bragg reflector bottom mirrors for high-performance VCSELs.

### I. Definitions

“Porosity,” as used herein refers to the volumetric ratio of air present in a porosified medium, such as a III-nitride layer(s), which is expressed as a percentage.

“Electropolishing,” as used herein, refers to an n-doped indium phosphide or gallium arsenide being etched away completely or substantially etched away (where “substantially etched away” refers to etching greater than 95%, 96%, 97%, 98%, or 99%) leaving a void where n-doped material originally existed. The void represents the low-index medium (i.e., air). The air typically has a refractive index of about 1.

“Refractive Index” or “Index of Refraction,” are used interchangeably and refer to the ratio of the velocity of light in a vacuum to its velocity in a specified medium, such as a layer of a III-nitride, according to the formula n=c/v, where c is the speed of light in vacuum and v is the phase velocity of light in the medium.

“Refractive Index Contrast,” as used herein refers to the relative difference in refractive index between two mediums having different indices of refraction and which are in contact and form an interface.

Numerical ranges include ranges of thicknesses, ranges of doping concentrations, ranges of integers, ranges of times, ranges of voltages, ranges of length, ranges of diameters, ranges of concentrations, etc. The ranges disclose individually each possible number that such a range could reasonably encompass, as well as any sub-ranges and combinations of sub-ranges encompassed therein. For example, a layer may have a thickness in the range of about 1 nm to 10 nm, where the range also discloses thicknesses that can be selected independently from about 2, 3, 4, 5, 6, 7, 8, and 9 nm, as well as any range between these numbers (for example, 3 nm to 8 nm), and any possible combination of ranges between these values.

Use of the term “about” is intended to describe values either above or below the stated value, which the term “about” modifies, in a range of approx. +/−10%; in other instances the values may range in value either above or below the stated value in a range of approx. +/−5%. When the term “about” is used before a range of numbers (i.e., about 1-5) or before a series of numbers (i.e., about 1, 2, 3, 4, etc.) it is intended to modify both ends of the range of numbers and/or each of the numbers recited in the entire series, unless specified otherwise.

### II. Multilayer Structures Containing Porous or Etched InP or GaAs Layers Therein

Multilayer structures made of indium phosphide (InP) or gallium arsenide (GaAs) which contain layers which are porous or etched (i.e., electropolished) within the structure are described in detail below.

In one instance, a non-limiting exemplary of the multilayer structure contains:
a plurality of undoped or low doped (see below) indium phosphide or gallium arsenide layers optionally present on a single-crystalline substrate formed of indium phosphide, gallium arsenide, sapphire, silicon, or silicon carbide,
where the multilayer comprises at least one layer of an n-doped indium phosphide or gallium arsenide which is present between at least two layers of undoped or low doped indium phosphide or gallium arsenide and the n-doped indium phosphide or gallium arsenide contains at least a region or portion that is porous or electropolished due to electrochemical etching, and
where the at least one layer of n-doped indium phosphide or gallium arsenide, when porous, contains a plurality of pores within the n-doped indium phosphide or gallium arsenide layer that are confined by adjacent undoped or low n-doped indium phosphide or gallium arsenide layers that are non-porous or substantially non-porous (where “substantially non-porous” refers to having a degree of porosity of less than 25%, 20%, 15%, 10%, 5%, 4%, 3%, 2%, or 1% in the undoped (or low doped) layers). In some other instances, the plurality of pores are horizontally aligned (i.e., parallel) with a plane direction of the n-doped indium phosphide or gallium arsenide layer.

In preferred embodiments, the multilayer structures are made of a single type of doped and undoped (or lowly doped) material. For example, a multilayer structure made of all indium phosphide layers or all gallium arsenide layers. However, in less preferred instances, a mixture of different types of materials is possible.

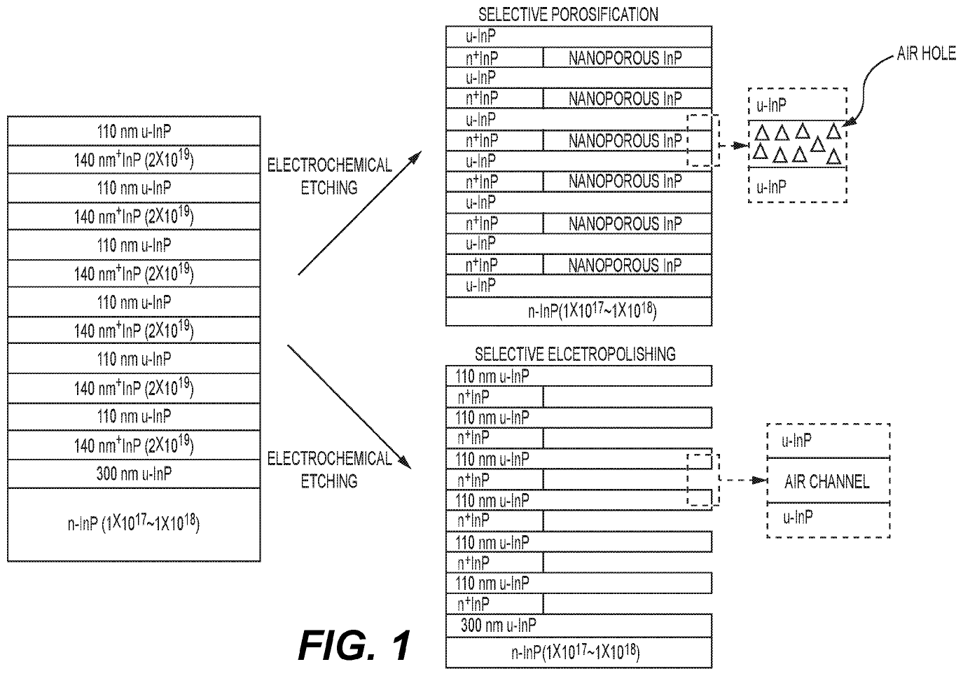

As shown in FIG. 1, the multilayer structure is formed of alternating layers of n-doped and undoped (or low doped) InP or GaAs. N-doped layers are present between undoped (or low doped layers). N-doped layers, which are sufficiently doped, can be selectively electrochemically etched, as described below, to selectively porosify the doped layer or to selectively electropolish (i.e., remove) the doped layers or regions within away. The undoped or low doped layers are generally not electrochemically etched. The conditions that control the degree of porosification or that permit electropolishing are described in further detail below. As can be seen from FIG. 1, porosification and electropolishing need not remove the entirety of the n-doped layer, where only a portion or region therein may be porosified or electropolished in the process. As can be further seen from FIG. 1, porosification and electropolishing forms multilayer structures which contain (air) pores or channels that form in a horizontal direction due to selective lateral etching which proceeds from one or more side walls of the multilayer structure.

In instances where the substrate is present it can be made of indium phosphide, gallium arsenide, sapphire, silicon, or silicon carbide of any suitable thickness. Preferably an undoped or low doped layer is the first layer deposited on the substrate. In most instances, the multilayer structure is formed of only one type of semiconductor material, InP or GaAs. The layers of alternating layers of n-doped and undoped (or low doped) InP or GaAs are homoepitaxially formed and controllably n-doped using art known techniques. In some instances, the alternating layers can be grown, for example, on a suitable substrate (i.e., c-plane of a sapphire substrate, a silicon substrate, or a silicon carbide substrate) by metal organic chemical vapor deposition (MOCVD). The doped and undoped layers are preferably planar layers. The dimensions of layer(s), whether doped or undoped, can be of any size, area, or shape suitable for a specific application. In some instances, the area is in the range of between about 0.1 to 100 cm², 0.1 to 90 cm², 0.1 to 80 cm², 0.1 to 70 cm², 0.1 to 60 cm², 0.1 to 50 cm², 0.1 to 40 cm², 0.1 to 30 cm², 0.1 to 20 cm², 0.1 to 10 cm², 0.1 to 5 cm², or 0.1 to 1 cm². Electrochemical etching requires that InP or GaAs be doped with an n-type dopant. Accordingly, doped layers, as present, are formed during deposition/formation. Exemplary dopants can include, but are not limited to, n-type Ge and Si dopants. Such dopant sources can include, for example, silane (SiH₄), germane (GeH₄), and isobutylgermane (IBGe). For n-type doped layers of InP or GaAs formed, the n-type doping concentration can be uniform across the entirety of the layer or the doping concentration may form a gradient (i.e., a layer having a graded dopant concentration across an axis of the layer, such width). The doping concentration is considered high at doping concentration levels of at least about 1×10¹⁹ cm⁻³ or higher; or is the range of between about 0.1×10¹⁹ cm⁻³ to 10×10²⁰ cm⁻³. In some cases, the high doping concentration level may be about 1×10¹⁹ cm⁻³, 2×10¹⁹ cm⁻³, 3×10¹⁹ cm⁻³, 4×10¹⁹ cm⁻³, 5×10¹⁹ cm⁻³, 6×10¹⁹ cm⁻³, 7×10¹⁹ cm⁻³, 8×10¹⁹ cm⁻³, 9×10¹⁹ cm⁻³, or 10×10¹⁹ cm⁻³. The doping concentration is considered to be moderate at doping concentration levels of greater than about 1×10¹⁸ cm⁻³ to less than 1×10²⁰ cm⁻³, 2×10¹⁸ cm⁻³ to less than 1×10²⁰ cm⁻³, 3×10¹⁸ cm⁻³ to less than 1×10²⁰ cm⁻³, 4×10¹⁸ cm⁻³ to less than 1×10²⁰ cm⁻³, or 5×10¹⁸ cm⁻³ to less than 1×10²⁰ cm⁻³. In some instances, the moderately doped concentration level is in the range of 1×10¹⁹ cm⁻³ to less than 1×10²⁰ cm⁻³ or in the range of about 0.5×10¹⁹ cm⁻³ to 10×10¹⁹ cm⁻³. In some cases, the moderate doping concentration level may be about 1×10¹⁸ cm⁻³, 2×10¹⁸ cm⁻³, 3×10¹⁸ cm⁻³, 4×10¹⁸ cm⁻³, 5×10¹⁸ cm⁻³, 6×10¹⁸ cm⁻³, 7×10¹⁸ cm⁻³, 8×10¹⁸ cm⁻³, 9×10¹⁸ cm⁻³, or 10×10¹⁸ cm⁻³. Moderate to high n-type doping is subject to the electrochemical etching process and results in controlled porosification and/or electropolishing of the doped layers, depending on the conditions used during the electrochemical etching process.

As noted above, the multilayer structure contains layers of undoped InP or GaAs, which are not affected (porosified or etched) when the multilayer structure is electrochemically etched. In general, the multilayer structure contains undoped layers of InP or GaAs. In some instances, however, the multilayer structure may contain layers of low doped InP or GaAs where the doping concentration is considered to be low at doping concentration levels of less than about 20×10¹⁷ cm⁻³ or in the range of between about 0.5×10¹⁷ cm⁻³ to 10×10¹⁷ cm⁻³. In some cases, the moderate doping concentration level may be about 1×10¹⁷ cm⁻³, 2×10¹⁷ cm⁻³, 3×10¹⁷ cm⁻³, 4×10¹⁷ cm⁻³, 5×10¹⁷ cm⁻³, 6×10¹⁷ cm⁻³, 7×10¹⁷ cm⁻³, 8×10¹⁷ cm⁻³, 9×10¹⁷ cm⁻³, or 10×10¹⁷ cm⁻³.

The number of alternating layers of n-doped and undoped (or low doped) InP or GaAs forming the multilayer structure prior to electrochemical etching is not particularly limited. In some instances, the alternating layers are formed such that there is an n-doped layer present between every undoped (or low doped) layer of InP or GaAs. In some cases, there may be 3 to 10 alternating layers (formed of a pair of n-doped and undoped (or low doped) layers of InP or GaAs). For example, FIG. 1 contains six pairs alternating n-doped and undoped (or low doped) layers at least prior to electrochemical etching (left side). In some instances, the multilayer architecture includes at least 6 pairs of n-doped and undoped (or low doped) layers of InP or GaAs which are in contact at least prior to electrochemical etching. In some other instances, the multilayer architecture includes at least 24 pairs if, after etching, a refractive index contrast of about 0.5 exists between etched and non-etched layers of InP or GaAs in order to achieve a theoretical reflectance of about 99.9%.

The thicknesses of any one of the n-doped or undoped (low doped) layers, prior to electrochemical etching, may each independently range in between about 50 to 500 nm (and subranges therein). In some instances, the total thickness of the multilayer structure, before or after electrochemical etching, may range from between about 600 nm to about 8,000 nm or 600 nm to about 6,000 nm, and sub-ranges within. The dimensions and/or shape of the layers or substrate may be of any suitable shape/dimension required for an application.

Following electrochemical etching, in the multilayer structures the undoped or low doped InP or GaAs layers are typically unaffected (i.e., non-porosified or substantially non-porosified (where “substantially non-porosified” refers to having a degree of porosity of less than 25%, 20, 15%, 10%, 10%, 5%, 4%, 3%, 2%, or 1% in the undoped (or low doped) layers). In some instances of the method, unintentional porosification of undoped (or lowly doped) layers occur, where even lowly n-doped layers can be porosified during EC etching.

Following electrochemical etching, in the multilayer structures the n-doped InP or GaAs layers can be porosified, as compared to prior to electrochemical etching. Porosification can be high where the layer contains at least one portion which has between about 30% and 90%, or greater porosity. In some instances, the porosity is at least about 30%, 40%, 50%, 60%, 70%, 80%, or 90% or greater. Incorporation of a low index material, such as air, into layer (or portion thereof) by porosification has the effect of lowering the refractive index, as compared to the bulk InP or GaAs before porosification.

For the n-doped layers, electrochemical etching can result in different degrees of porosities and pore morphologies by changing the type and concentration of electrolyte, n-doping concentration of the layers, and applied bias voltage, as discussed in greater detail in Section III below.

Electrochemical etching can be used to selectively create lateral or horizontal pores in the multilayer structure. These selectively form from side surfaces of the multilayer structure, as shown in FIG. 1. Without limitation, lateral or horizontal pores formed during the electrochemical etching process may be of any suitable length. Porosified InP or GaAs layers (or regions therein) contained within the multilayer structures are preferably nanoporous but may be further defined as being micro-, meso-, or macro-porous, or any combination thereof. The porosified layer or region therein may be further categorized as microporous (d<2 nm), mesoporous (2 nm<d<50 nm), or macroporous (d>50 nm); where d is the average pore diameter. The morphology of the pores contained within the layer or region therein can also be classified as circular, semicircular, ellipsoidal, or a combination thereof. The pores may have an average size (i.e., length) of between about 5 to 100 nm, 5 to 75 nm, 5 to 50 nm, or 5 to 25 nm. In some instances, the average pore size is about 5, 10, 20, 30, 40, 50, 60, 70, 80, 90, 100 nm or greater. In some instances, based on the original doping concentration, the etchant used, and the applied voltage during the electrochemical porosification process, the average size of the pores can range from between less than about 20 nm to greater than 50 nm. The spacing between any adjacent pores (which is also defines a measure of wall thickness of the pores) can range from between about 1 to 50 nm, 5 to 50 nm, 5 to 40 nm, 5 to 30 nm, 5 to 25 nm, 5 to 20 nm, 5 to 15 nm, or 5 to 10 nm.

In a given multilayer structure, all or a portion of the doped InP or GaAs layer may be porosified during electrochemical etching. In some instances, electrochemical etching proceeds from a side wall and the extent of porosification of a layer is at least about 10, 20, 30, 40, 50, 60, 80, or 90% of the longest planar dimension of the doped layers. In some other instances, where electropolishing occurs, the extent of electropolishing of a layer is at least about 10, 20, 30, 40, 50, 60, 80, or 90% of the longest planar dimension of the doped layers. Porosification may occur uniformly or non-uniformly within each doped layer during the electrochemical etching process. Electropolishing may occur uniformly or non-uniformly within each doped layer during the electrochemical etching process.

As noted above, in some instances the doped layer is electropolished away (completely removed) which leaves little or no material between the undoped (or low doped) layers, where the doped InP or GaAs material used to be. The dimensions of the void space formed due to electropolishing depends on the dimensions of the doped InP or GaAs layer and the extent of material that was electropolished away. As shown in FIG. 1, electropolishing creates lateral or horizontal (air) pores or channels between the undoped layers where the doped material has been removed.

### a. Optical Properties of Multilayer Structures

Selective incorporation of a low index material, such as air, into selected regions of the multilayer structures by electrochemically etching has the effect of lowering the refractive index, as compared to the bulk InP or GaAs. Thus, it is possible to tune the refractive index of the porosified regions within the multilayer structure selectively.

Prior to electrochemical etching, in multilayer structures formed of InP each of the layers has an index of refraction of about 3.2. Electrochemical etching, selectively porosifies or may completely electropolish doped InP layers which lower the index of refraction below 3.2. In some instances, the index of refraction of porosified InP layers is about 1.5 to 2.7. When the InP layers are electropolished away the index of refraction is about 1. Consequently, the refractive index contrast (Δn) between the InP layers, after electrochemical etching, may be in the range of about 0.5 to about 2. In some instances, the refractive index contrast (Δn) is at least about 1.1, 1.2, 1.3, 1.4, or 1.5. In still other instances, the refractive index contrast ratio (Δn) is at least about 1.5.

Prior to electrochemical etching, in multilayer structures formed of GaAs each of the layers has an index of refraction of about 3.95. Electrochemical etching, selectively porosifies or may completely electropolish doped InP layers which lower the index of refraction below 3.95. In some instances, the index of refraction of porosified GaAs layers is about 1.5 to 3.4. When the GaAs layers are electropolished away the index of refraction is about 1. Consequently, the refractive index contrast (Δn) between the GaAs layers, after electrochemical etching, may be in the range of about 0.5 to about 2.5. In some instances, the refractive index contrast (Δn) is at least about 1.1, 1.2, 1.3, 1.4, or 1.5. In still other instances, the refractive index contrast ratio (Δn) is at least about 1.5.

As discussed in the Examples below, forming layers of alternating indices of refraction can create successive constructive or destructive interferences. When the thicknesses of each layer corresponds to, respectively, ¼ of the optical wavelength, the stack of alternating layers of the multilayer structure together act as a reflective mirror that can be used to support the long wavelengths needed for infrared emitting VCSELs. In certain instances, the multilayer structure acts as a mirror and demonstrates a reflectance of at least about 99%, 99.1%, 99.2%, 99.3%, 99.4%, 99.5%, 99.6%, 99.7%, 99.8%, or 99.9%.

### b. Electrical Properties of Multilayer Structures

Selective incorporation of air by porosification or electropolishing into selected regions of doped layers in a multilayer structure by electrochemical etching can affect electrical properties, as compared to the bulk (non-porous) equivalent InP or GaAs. For electrically injected devices, especially those requiring high current densities, good electrical transport is essential for high device performance.

In some instances, porosification of regions of the doped InP or GaAs layers or electropolishing of regions of the doped InP or GaAs layers results in a multilayer structure where it is possible to retain a carrier (electron) concentration of above about 5×10¹⁸ cm⁻³ and electrical mobilities of at least about 50, 60, 70, 80, 90, 95 cm²/V s, or greater, compared to the bulk (non-porous) equivalent bulk InP or GaAs.

### c. Thermal Properties of Multilayer Structures

Selective incorporation of air by porosification or electropolishing into selected regions of doped layers in a multilayer structure by electrochemical etching can affect thermal properties, as compared to the bulk (non-porous) equivalent InP or GaAs.

In some instances, porosification of regions of the doped InP or GaAs layers or electropolishing of regions of the doped InP or GaAs layers results in a multilayer structure where the thermal conductivity of the multilayer structure, as a whole, in the range of between about 1 to 25, 2 to 20, 2 to 15, or 2 to 10 W/m·K. In still some other instances, the average thermal conductivity is at least about 1, 2, 3, 4, 5, 6, 7, 8, 9, 10, 11, 12, 13, 14, or 15 W/m·K.

### III. Methods of Preparing the Multilayer Structures

Unlike the photoelectrochemical (PEC) methods previously used, the conductivity selective electrochemical (EC) etching methods rely on electrically injected holes, rather than photogenerated holes, to oxidize doped indium phosphide or gallium arsenide permitting their selective porosification or electropolishing. The methods do not require exposure to ultraviolet (UV) illumination.

In one non-limiting example of a method of forming a multilayer structure, the method includes the steps of:
(a) forming a first layer of undoped or low doped indium phosphide or gallium arsenide above an optional substrate layer;
(b) depositing a second layer of an n-doped indium phosphide or gallium arsenide over the first layer;
(c) depositing a third layer of undoped or low doped indium phosphide or gallium arsenide above the second layer;
(d) optionally repeating steps (b) and (c) to form additional alternating layers the n-doped indium phosphide or gallium arsenide and the undoped or low doped indium phosphide or gallium arsenide;
(e) depositing a capping layer over the entire multilayer structure;
(f) removing at least a portion of the capping layer to selectively expose at least one sidewall of the multilayer structure; and
(g) electrochemically (EC) etching n-doped indium phosphide or gallium arsenide layers in the presence of an electrolyte and under an applied bias voltage to selectively porosify or electropolish at least a portion of the n-doped indium phosphide or gallium arsenide layers present;
where the n-doped indium phosphide or gallium arsenide layers, when porosified, comprise a plurality of pores within the n-doped indium phosphide or gallium arsenide layer that are confined by adjacent undoped or low n-doped indium phosphide or gallium arsenide layers that are non-porous or substantially non-porous (where “substantially non-porous” refers to having a degree of porosity of less than 25%, 20%, 15%, 10%, 5%, 4%, 3%, 2%, or 1% in the undoped (or low doped) layers). In some other instances, the plurality of pores are horizontally aligned (i.e., parallel) with a plane direction of the n-doped indium phosphide or gallium arsenide layer.

In preferred embodiments of the method, the multilayer structures are fabricated from a single type of doped and undoped (or lowly doped) material. For example, the multilayer structure is made of all indium phosphide layers or all gallium arsenide layers. However, in less preferred instances of the method, it is possible to use different types of materials (i.e., InP and GaAs together).

For the method described above, the substrate, when present, may be a sapphire, silicon, or silicon carbide substrate, or may be made of a preferably undoped indium phosphide or gallium arsenide layer. The single-crystalline substrate may have any suitable thickness.

The undoped or low doped indium phosphide or gallium arsenide layers, as well as the n-doped indium phosphide or gallium arsenide layers, can each be epitaxially or homoepitaxially grown according to art known methods, such as metal organic chemical vapor deposition (MOCVD) or molecular beam epitaxy (MBE).

In the methods, undoped or low doped indium phosphide or gallium arsenide layers, as well as the n-doped indium phosphide or gallium arsenide layers, as present, may each independently range between about 50 to 500 nm (and subranges therein). The thicknesses of the substrate or substrate layer, as may be present, may each independently have any suitable size but may range from about 50 to 500 nm (and subranges therein). The dimensions and/or shape of the above layers or substrate may be of any suitable shape/dimension required for an application. Lastly, the total thickness of the multilayer structure formed by the method preferably ranges from between about 600 nm to about 8,000 nm or about 600 nm to about 6,000 nm.

Depositing n-doped indium phosphide or gallium arsenide layers, as present, requires use of a dopant during deposition/formation. Exemplary dopants can include, but are not limited to n-type Ge and Si dopants. Such dopant sources can include, for example, silane (SiH₄), germane (GeH₄), and isobutylgermane (IBGe). The doping concentration can be uniform across the entirety of a doped III-nitride layer or the doping concentration may form a gradient (i.e., a graded dopant concentration across an axis of the layer, such width). The doping concentration is considered high at doping concentration levels of at least about 1×10¹⁹ cm⁻³ or higher; or is the range of between about 0.1×10¹⁹ cm⁻³ to 10×10²⁰ cm⁻³. The doping concentration is considered to be moderate at doping concentration levels of greater than about 1×10¹⁸ cm⁻³ to less than 1×10²⁰ cm⁻³, 2×10¹⁸ cm⁻³ to less than 1×10²⁰ cm⁻³, 3×10¹⁸ cm⁻³ to less than 1×10²⁰ cm⁻³, 4×10¹⁸ cm⁻³ to less than 1×10²⁰ cm⁻³, or 5×10¹⁸ cm⁻³ to less than 1×10²⁰ cm⁻³. In some instances, the moderately doped concentration level is in the range of 1×10¹⁹ cm⁻³ to less than 1×10²⁰ cm⁻³ or in the range of about 0.5×10¹⁹ cm⁻³ to ×10¹⁹ cm⁻³. Moderate to high n-type doping is subject to the electrochemical etching process and results in controlled porosification and/or electropolishing of the doped layers, depending on the conditions used during the electrochemical etching process. As noted previously, the multilayer structure contains layers of undoped InP or GaAs, which are not affected (porosified or etched) when the multilayer structure is electrochemically etched. In general, the multilayer structure contains undoped layers of InP or GaAs. In some instances of the method described, the multilayer structure may contain layers of low doped InP or GaAs where the doping concentration is considered to be low at doping concentration levels of less than about 20×10¹⁷ cm⁻³ or in the range of between about 0.5×10¹⁷ cm⁻³ to 10×10¹⁷ cm⁻³.

In step (e) a capping layer is deposited over the entire multilayer structure, where the capping layer may be made of a silicon oxide (i.e., SiO₂) or other suitable material, such as silicon nitride (SiNₓ), hafnium oxide (HfO₂), and photoresist material. Suitable photoresist materials are known in the art. The capping layer can have any suitable thickness needed and can be in a range of between 10 to 3000 nm. The capping layer can be epitaxially or homoepitaxially grown according to art known methods, such as metal organic chemical vapor deposition (MOCVD) or molecular beam epitaxy (MBE), plasma-enhanced chemical vapor deposition (PECVD), atomic layer deposition (ALD), physical vapor deposition (PVD), and sputter.

In step (f) removal of at least a portion of the capping layer to selectively exposes at least one sidewall of the multilayer structure to enable the EC process of step (g) to proceed at the exposed sidewall(s). Suitable techniques for removal of the capping layer, such as silicon dioxide layer, can include, for example, inductively coupled plasma reactive-ion etching (ICP-RIE), which can be used to etch the capping layer in a selective manner to expose the doped layer(s) at the sidewall(s) of the multilayer structure. Alternatively, a capped structure may be physically cleaved in order to expose the doped layer(s) at the sidewall(s) of the multilayer structure.

Porosification and/or electropolishing occurs during the electrochemical (EC) etching process of step (g) and can be controlled based on the concentration of electrolyte, doping concentration, and applied bias voltage (as discussed below). The applied bias voltage is typically a positive voltage in the range of about 0.1 to 10 V, 1.0 to 5V, or 1.0 to 2.5V. In some instances, based on the original doping concentration and the type of etchant used, the applied bias ranges from less than about 1V to at least about 10V, or greater. In some instances, porosity can be selectively minimized when lower relative doping concentration(s) are used, where in one non-limiting instance, a doping concentration of 5×10¹⁸ cm⁻³ in a sample produces a lower porosity as compared to a doping concentration of 2×10¹⁹ cm⁻³ when both are etched under the same conditions. This can be generally expected for all relative concentration differences, where the higher doping concentration will be subject to greater porosification when compared to a lower relative doping concentration, all other electrochemical etching parameters being constant. In some instances, depending on concentration of electrolyte, doping concentration, and selection of applied bias voltage applied voltage(s), electrochemical etching conditions may selectively and controllably result in only porosification (having between about 30% and 90%, or greater porosity introduced) or complete electropolishing (i.e., total or near total removal (i.e., greater than 95%, 96%, 97%, 98%, or 99% removal of doped material). The electric field direction during the EC etching process can be used to control the direction of the etching direction and thereby control the direction of the pores etched into the doped InP or GaAs layer. For example, during step (g) of the methods, the EC etching direction may be a function and determined by the electric field direction. The EC etching preferably produces a lateral etching direction. The rate of lateral etching during step (g) can be about 0.1 μm/min, 0.2 μm/min, 0.3 μm/min, 0.4 μm/min, 0.5 μm/min, 0.6 μm/min, 0.7 μm/min, 0.8 μm/min, 0.9 μm/min, 1 μm/min, 2 μm/min, 3 μm/min, 4 μm/min, 5 μm/min, 6 μm/min, 7 μm/min, 8 μm/min, 9 μm/min, 10 μm/min, 20 μm/min, 30 μm/min, 40 μm/min, or 50 μm/min.

The EC etching of step (g) can be carried out under an applied bias voltage from about 1 min to 24 hours, 1 min to 12 hours, 1 min to 6 hours, 1 min to 4 hours, 1 min to 2 hours, 1 min to 1 hour, or 1 min to 30 minutes. In some instances, the EC etching of step (g) is carried out under an applied bias voltage for at least about 5 min, 10 min, 15 min, 20 min, 25 min, 30 min, 35 min, 40 min, 45 min, 50 min, 55 min, 60 min, 2 hours, 3 hours, 4 hours, 5 hours, 6 hours, 10, hours, 15 hours, 20 hours, 24 hours, or greater. The EC etching of step (g) can be carried out under an applied bias voltage at room temperature or at a temperature in the range of about 10° C. to about 50° ° C. The EC etching of step (g) can be carried out under an applied bias voltage under ambient conditions or optionally under an inert atmosphere (such as of nitrogen or argon).

The EC etching carried out in step (g) can be carried out in different types and concentrations of a high conductivity electrolyte (either salt or acid). Exemplary high conductivity electrolytes can include, but are not limited to halide ions (fluoride, chloride, bromide, iodide), hydrochloric acid (HCl), sulfuric acid (H₂SO₄), hydrofluoric acid (HF), KOH, NaOH, Ba(OH)₂, Ca(OH)₂, Sr(OH)₂, NH₄OH, NaCl, NaF, nitric acid (HNO₃), organic acids and their salts (such as oxalic acid and citric acid), and mixtures thereof. The concentration of the electrolyte in the high conductivity electrolyte solutions, typically aqueous, can be in the range of between about 0.1 to 10M. In some other instances, concentration of the electrolyte in the high conductivity electrolyte solutions, typically aqueous, can be defined as a percentage (volume/volume) of the electrolyte to solvent(s), such as water, in which it is dissolved in and can be in the range of between about 0.1 to 30% by volume. In still other instances, concentration of the electrolyte in the high conductivity electrolyte solutions, typically aqueous, can be defined as a percentage (weight/volume) of the electrolyte to solvent(s), such as water, in which it is dissolved in and can be in the range of between about 0.1 to 30% by weight. The electrolytes listed above normally do not etch InP or GaAs at room temperature, but can etch InP or GaAs under an electrochemical anodic conditions applied during step (g).

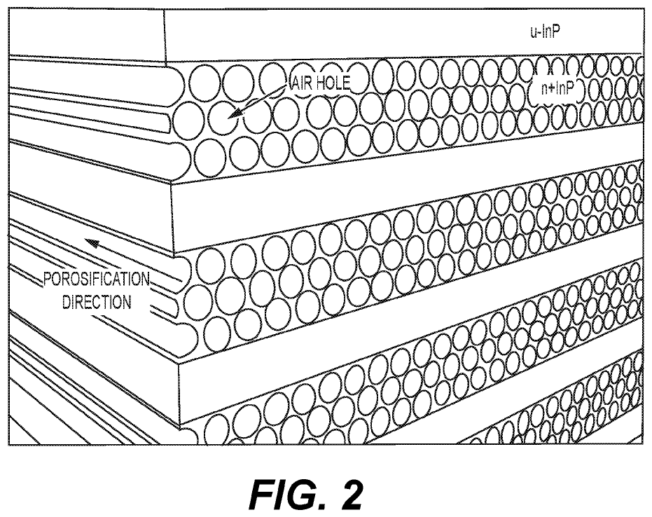

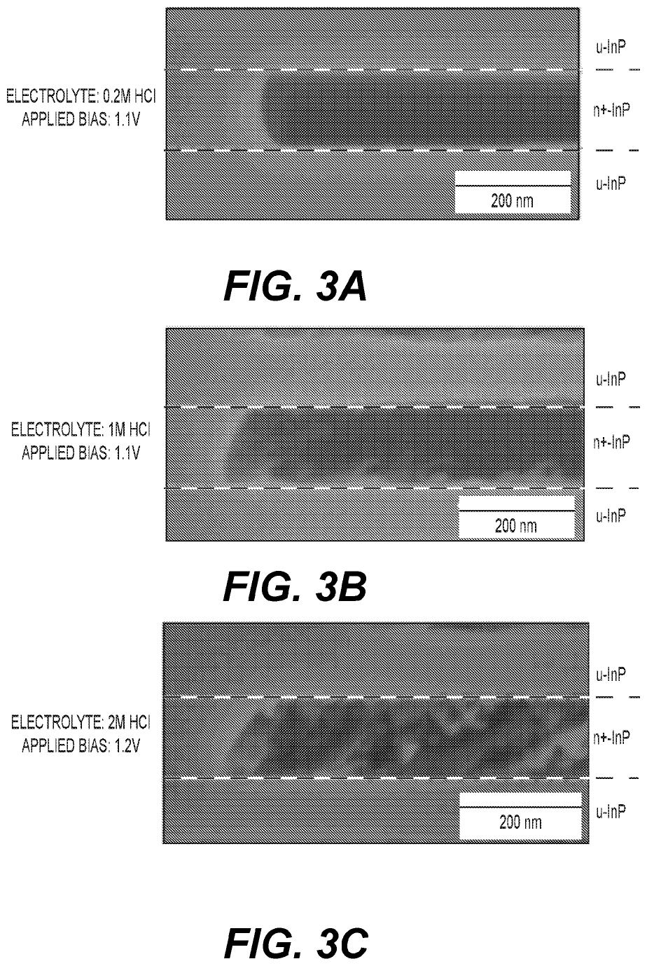

It is believed that electrochemical etching, as described above, proceeds from the edge of the exposed sidewall(s), such as in a lateral direction to preferentially form horizontal pores. Lateral etching causes porosification producing pores, typically nanopores, to be formed horizontally or predominantly horizontally within a doped layer during step (g). The multilayer structure has a vertical axis from the lowest to the top-most layer where planar layers of alternating doped and undoped (or lowly doped) InP or GaAs exist. When EC etching is induced, porosification of n-doped layers occurs perpendicular or predominantly perpendicularly to the vertical axis. Predominantly perpendicular, as used herein, refers to pores that, on average, are oriented within about 20, 15, 10, or 5 degrees of the perpendicular/horizontal plane to the vertical axis. In other words, porosification occurs along or predominantly along a horizontal direction that is parallel or near parallel to the planar direction of doped layers. See FIG. 2. For the multilayer structures, following electrochemical etching, there should be little, if any, pores that are vertically aligned with the vertical axis. Pores are preferably not aligned with the vertical axis of the multilayer structure. In some instances, no vertically aligned pores are formed in the doped layers and only horizontal pores are formed during electrochemical etching (see FIG. 2). In some instances, substantially non-porosified undoped (or lowly doped) InP or GaAs also has nanopores formed along the [111] crystallographic direction, which is at an angle of 45 degree inclined from vertical [001] and horizontal directions. In some other instances, it may be the said that macroscopically nanopores formed in n-doped InP laterally propagate during porosification, while microscopically nanopore generation can occur along a specific crystallographic directions (such as, +45°, −45° inclined from the doped layer surface).

Electrochemical etching generally consists of oxide formation and removal steps (Quill, N., et al. (2013). ECS transactions, 58(8), 25-38). It is believed that the presence of free holes at InP or GaAs/electrolyte interface is important for oxidation, and oxides formed can be easily dissolved in the various electrolytes. The free holes are supplied by electric-field assisted tunneling and their amount mainly depends on anodic bias and doping concentration. In some instances, electrochemical (EC) etching conditions result in no EC etching at low anodic bias and/or low doping concentrations (low doping is described above), whereas electropolishing (i.e., complete etching) is observed at large bias and/or high n-doping concentrations. Porosification is observed at intermediate bias and/or doping concentrations.

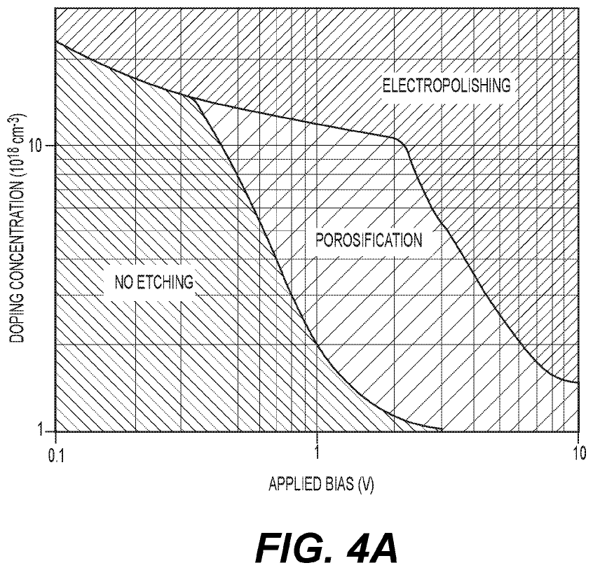

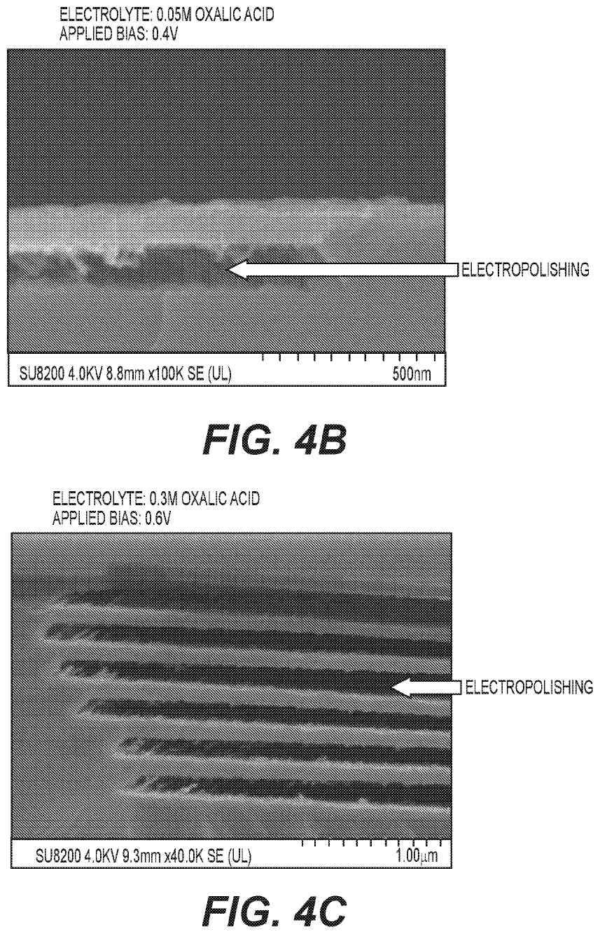

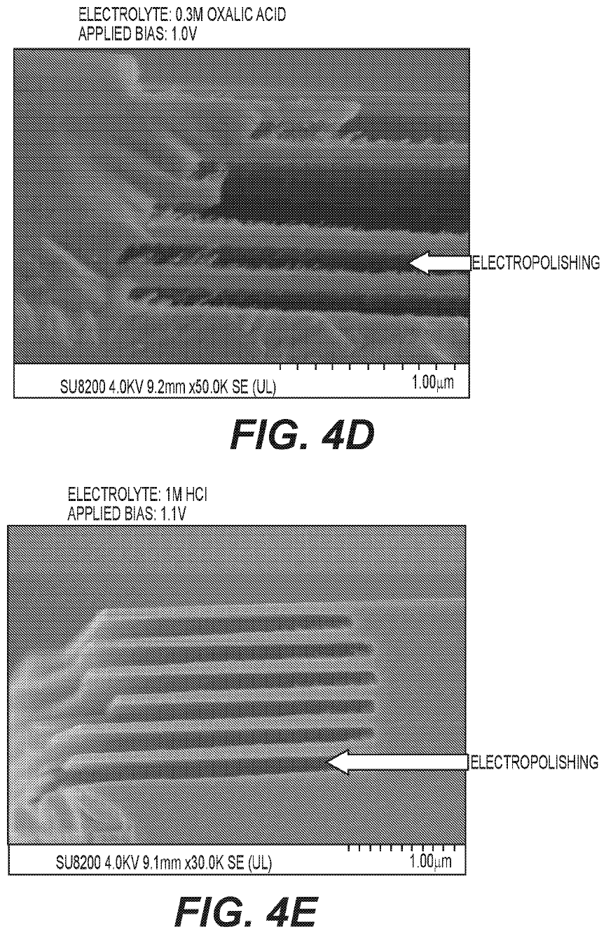

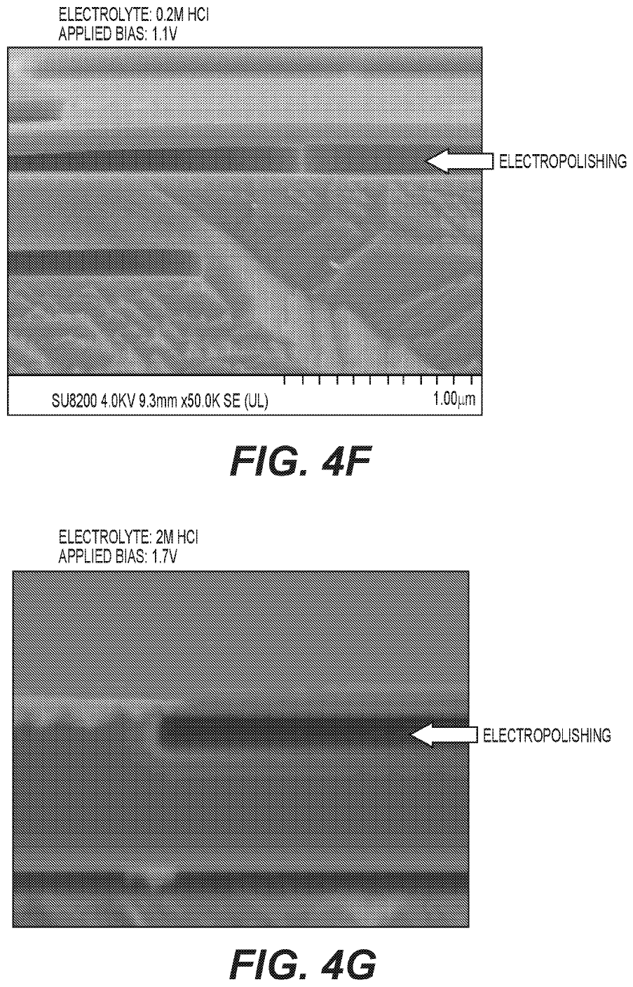

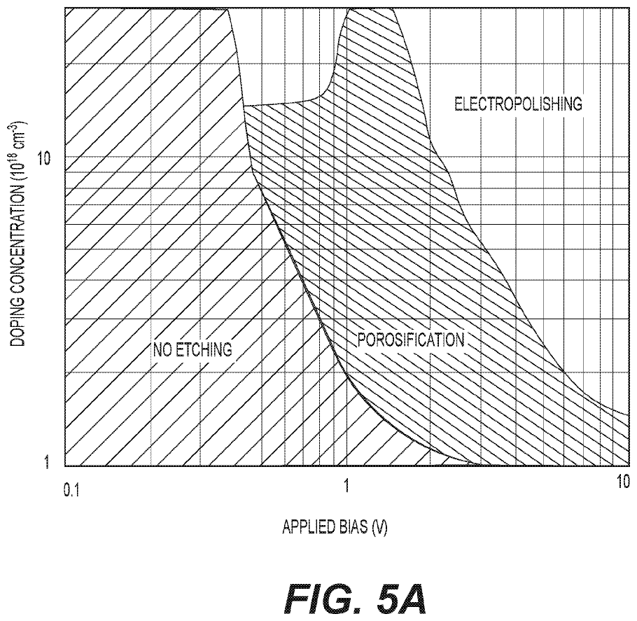

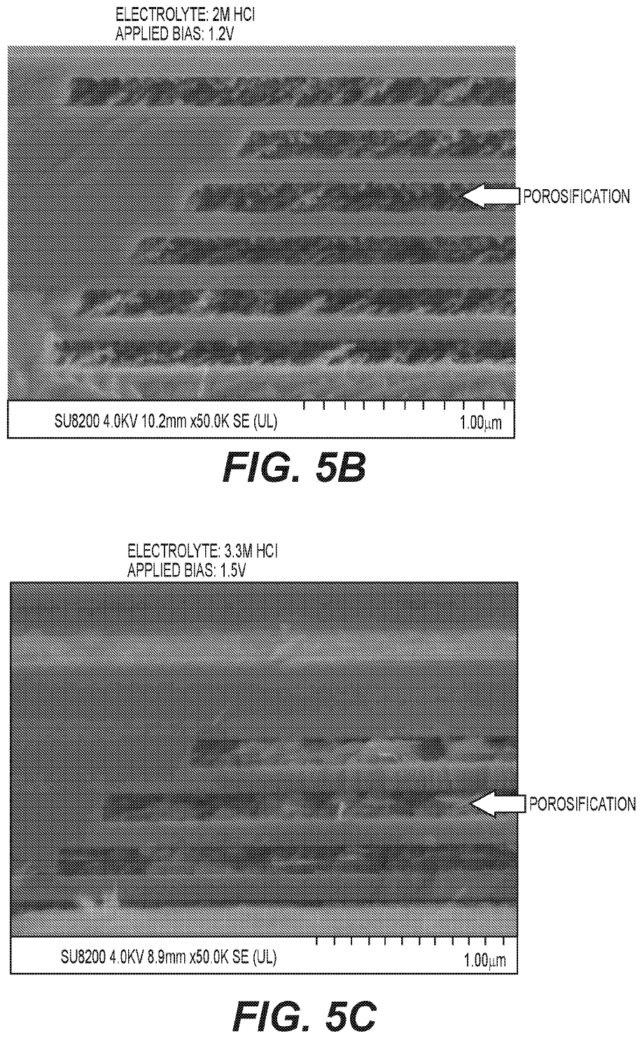

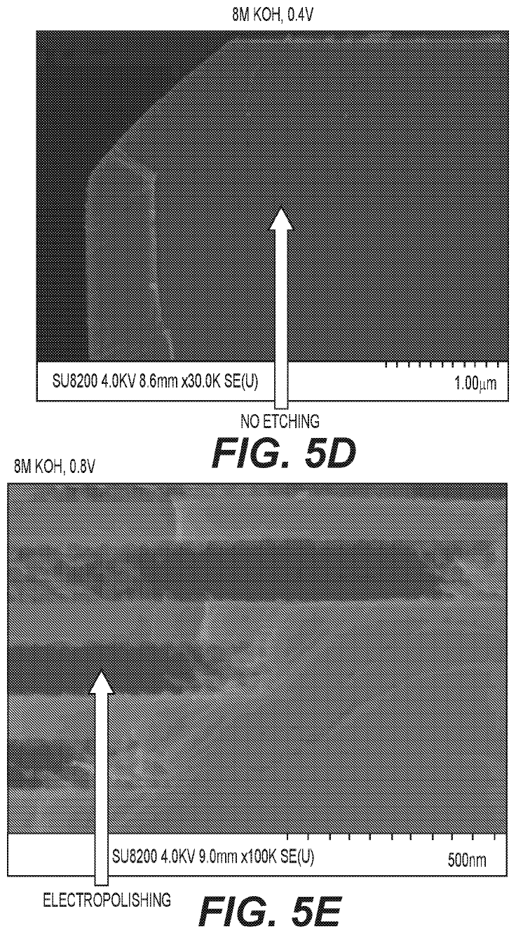

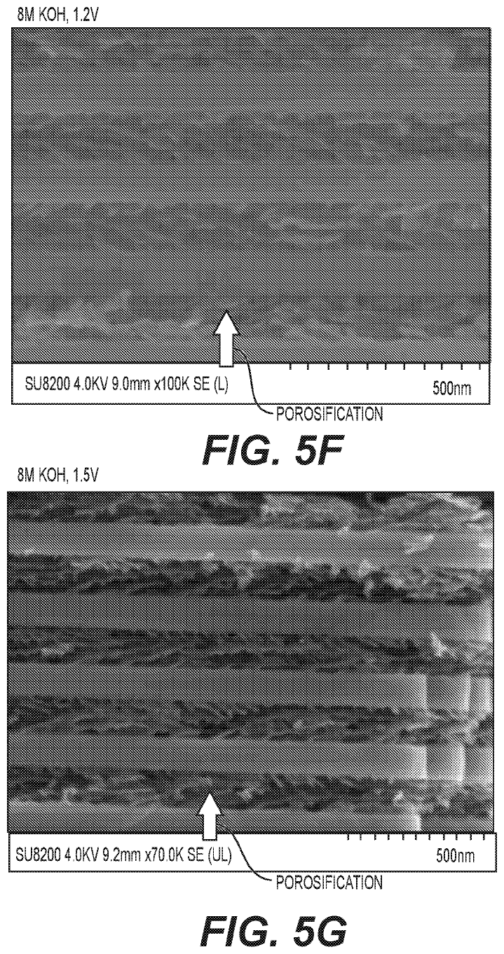

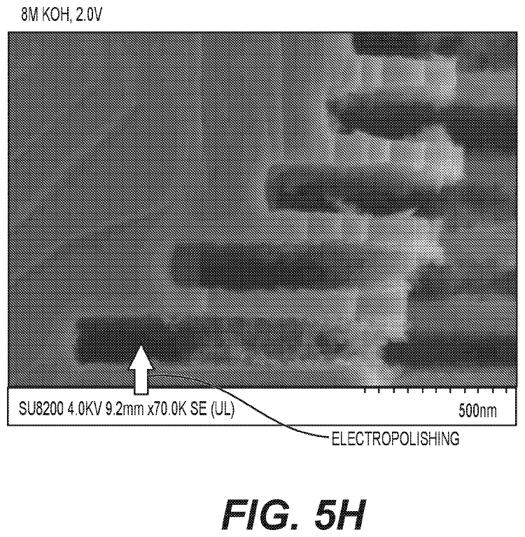

Indium phosphide can demonstrate complex electrochemical (EC) etching behavior, particularly when high doping concentrations are used in the InP layers. FIGS. 4A and 5A show exemplary EC etching phase diagrams derived experimentally by etching InP multilayer structures, such as shown in FIG. 1, in various electrolytes (HCl, oxalic acid, and KOH at varying concentrations) and at varying applied voltages. It was found that once the doping concentration of the indium phosphide layer is close to or exceeds 1×10¹⁹ cm⁻³, electrolyte concentration-dependent EC etching becomes dominant, and affects the porosification process. As shown in FIGS. 4A and 5A, doped InP tends to be primarily electropolished in electrolytes having a concentration of less than about 2M at applied voltages ranging from about 0.1 to about 2V. It was also found that more concentrated electrolytes, such as above about 2M concentrations, allows porosification but also displays a voltage dependence where voltages below 1V either produce no etching (i.e., below 0.5V) or produce electropolishing (i.e., between 0.5V to 1V) and voltages above 1V produce porosification. See, for example, FIGS. 5D-5H. Therefore, the choice of electrolyte is one of the most important steps to porosify the n⁺-InP and achieve good EC etching selectivity. In general, the trends observed for InP could be expected in a comparable multilayer architecture made of GaAs.

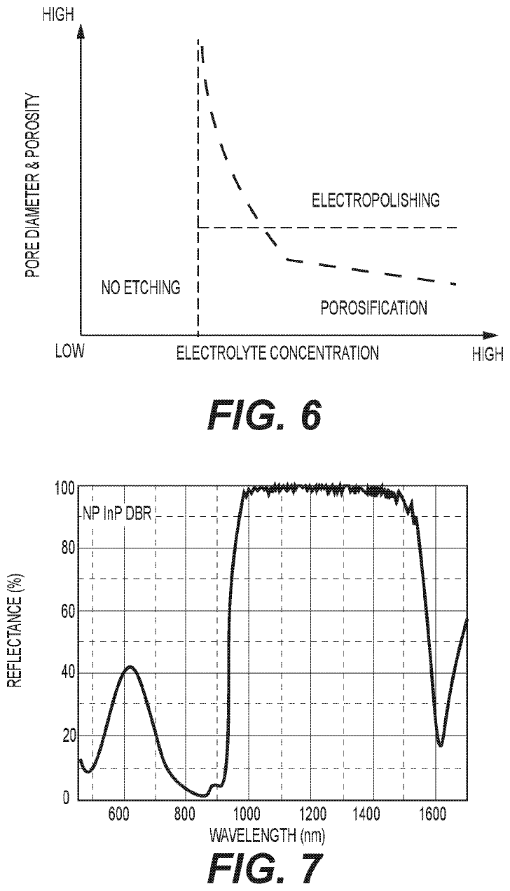

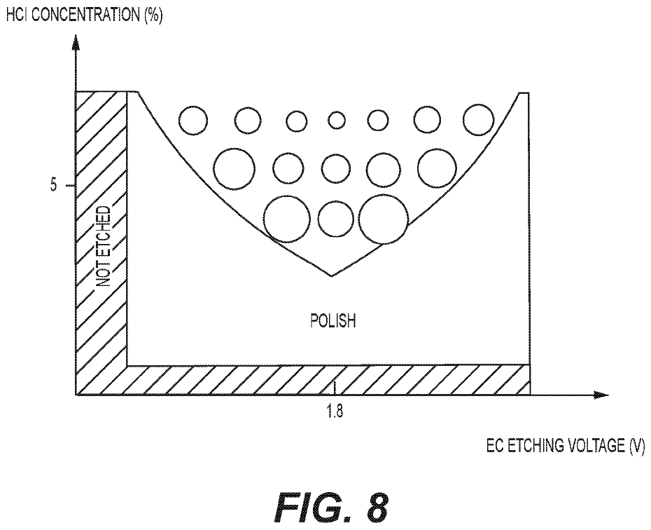

It is also believed that the free holes created at pore tips are quickly consumed and participate in InP oxidation, which can result in a short hole diffusion length and can prevent EC etching of the walls between nanopores. In the case of heavily doped InP (n≥1×10¹⁹ cm⁻³), a small depletion width leads to ultra-thin pore walls, and nanopores could easily collapse, depending on electrolyte choice due to hole diffusion. The short hole diffusion length and/or passive layers formed on the pore walls are required for porosification of doped InP. The concentration of electrolyte can be increased to satisfy these conditions and can be used to achieve selective porosification of doped InP (see FIG. 6).

### IV. Methods of Using the Multilayer Structures

The multilayer structures can be used in various applications including electronic, photonic, and optoelectronic applications. Applications for such multilayer structures include, more specifically, fiber-based communications, free-space communications, LiDAR, sensing and range-finding, night vision, and chemical sensing, among others.

In particular, the multilayer structures are useful in laser diodes, such as vertical-cavity surface-emitting lasers (VCSELs) where they can serve as distributed Bragg reflectors (DBRs). Multilayer structures used as a DBR made of indium phosphide should be able to provide long-wavelength VCSELs (i.e., emitting at infrared wavelengths from 900 to 2000 nm). Multilayer structures used as a DBR made of gallium arsenide should be able to provide VCSELs which can emit in the range of between about 800 to 1100 nm. The multilayer structures can be incorporated into different devices, such as VCSELs, using art known techniques.

The multilayer structures fabricated and etched in these examples possess a high index contrast, are lattice-matched, epitaxially compatible, and allow for manufacture-friendly fabrication of mirrors, DBRs, for VCSELs. When multilayer structures are formed of InP they can be used to produce long-wavelength VCSELs. The methods described above can allow for the mass production of DBRs based on the multilayer structures, such as made of indium phosphide, to produce infrared VCSELs emitting at 1200 to 2000 nm.

These multilayer structures, when EC etched, can demonstrate primarily or exclusively horizontal porosification in a layered, selective way. This is especially important in VCSEL applications, as horizontal porosification can be made without adversely affecting the quality of the active region that is typically grown on top of the DBR layers.

In certain instances, the multilayer structure acts as a DBR in a vertical cavity surface emitting laser (VCSEL) demonstrating a stopband at or around 1100 to 2000 nm for indium phosphide with a peak reflectance of at least about 99%, 99.1%, 99.2%, 99.3%, 99.4%, 99.5%, 99.6%, 99.7%, 99.8%, or 99.9%. In certain instances, the multilayer structure acts as a DBR in a vertical cavity surface emitting laser (VCSEL) demonstrating a stopband at or around 1250 nm with a peak reflectance of at least about 99%, 99.1%, 99.2%, 99.3%, 99.4%, 99.5%, 99.6%, 99.7%, 99.8%, or 99.9%. In some instances, the stopband has a wavelength width of between about 800 to 1100 nm for gallium arsenide with a peak reflectance of at least about 99%, 99.1%, 99.2%, 99.3%, 99.4%, 99.5%, 99.6%, 99.7%, 99.8%, or 99.9%. Such properties can be tailored by tuning the properties of the multilayer structure, such as the number of layers, the thicknesses of the layers, the extent of porosification or electropolishing of doped layers by EC etching.

The multilayer structures can be used to provide high performance VCSELs with excellent optical and electrical performance, as compared to previously reported VCSELs. VCSELs have many advantages compared to more commonly used edge emitting laser diodes (EELDs), such as superior beam quality, compact form factor, low operating power, cost-effective wafer-level testing, higher yield and lower cost in manufacturing. VCSELs, in general, find important applications in various fields including information processing, micro-display, pico-projection, laser headlamps, high-resolution printing, biophotonics, spectroscopic probing, and atomic clocks.

The present invention will be further understood by reference to the following non-limiting examples.

### Example 1: Preparation and Testing of InP Multilayer Structures (High Doping)

### Materials and Methods

Multilayer structures were formed from indium phosphide was homoepitaxially grown on single side polished n-InP substrate by MOCVD. Doped layers were doped with germanium dopant at the doping concentrations listed below. The multilayer structure contained alternating layers of n-doped (2×10¹⁹ cm⁻³) and undoped InP layers. A base layer was formed of an n-doped InP layer with a doping concentration of only 1×10¹⁷ to 1×10¹⁸ onto which a 300 nm layer of undoped InP was formed. A 140 nm n-doped InP layer was deposited onto the 300 nm layer. Then, a 110 nm layer of undoped InP was deposited onto the 140 nm layer. Additional layers of doped InP (140 nm; 2×10¹⁹ cm⁻³) and undoped InP (110 nm) were deposited. The final layer of InP was undoped. The structure is represented in FIG. 1 (see left). The final multilayer structure contained six doped InP layers (140 nm; 2×10¹⁹ cm⁻³) in between undoped InP layers. Then, a capping layer of silicon dioxide was deposited onto the entire multilayer structure and a side wall of the multilayer structure was exposed by removal of selected portion of the silicon dioxide layer by plasma-enhanced chemical vapor deposition and wafers are cleaved into narrow bars in order to expose the sidewalls of doped InP layers for electrochemical etching.

Subsequently, the multilayer structures were electrochemically (EC) etched in various concentrations of aqueous electrolytes (HCl, oxalic acid, and KOH) and at different anodic voltages, according to the methods described above. The anodic voltages were applied for 5 to 20 mins. For testing performed, HCl demonstrated a fast lateral etch rate (about 8-20 μm/min), whereas KOH showed a slower lateral etch rate (about 0.1-0.5 μm/min). The conditions tested and observed results are provided in Table 1 below.

TABLE 1

| Electrolyte | Anodic Voltage | Observations |
|---|---|---|
| 0.2M HCl | 1.1 V | Doped InP electropolished |
| 1M HCl | 1.1 V | Doped InP electropolished |
| 3.3M HCl | 1.5 V | Doped InP porosified |
| 2M HCl | 1.2 V | Doped InP porosified |
| 2M HCl | 1.7 V | Doped InP electropolished |
| 0.05M Oxalic acid | 0.4 V | Doped InP electropolished |
| 0.3M Oxalic acid | 0.6 V | Doped InP electropolished |
| 0.3M Oxalic acid | 1.0 V | Doped InP electropolished |
| 8M KOH | 0.4 V | Doped InP not etched |
| 8M KOH | 0.8 V | Doped InP electropolished |
| 8M KOH | 1.2 V | Doped InP porosified |
| 8M KOH | 1.5 V | Doped InP porosified |
| 8M KOH | 2.0 V | Doped InP electropolished |

Scanning electron microscopy images of the above are shown in FIGS. 4B-4G and 5B-5H.

### Results

The results of electrochemically etching revealed that lateral etching produced horizontal and/or substantially horizontal pores, when porosification occurred. Layers that were porosified were found to be nanoporous after etching.

Dependent on the EC conditions used, including the electrolyte choice and concentration and bias voltage, the doped InP layers could be electropolished. When using an HCl electrolyte, for example, doped InP was electropolished at or below 2 molar concentration (M) of HCl, whereas at 2 and 3.3 M HCl nanopores were formed even at relatively higher anodic voltages (see FIGS. 4E-4G and 5B-5C). This EC etching behavior was also seen in KOH. It is believed that the free holes created at pore tips are quickly consumed and participate in InP oxidation, resulting in a short hole diffusion length and can prevent EC etching of the walls between nanopores. In the case of heavily doped InP (n≥1×10¹⁹ cm⁻³), a small depletion width leads to the ultra-thin pore walls, and therefore nanopores could easily collapse in depending on electrolyte choice due to hole diffusion. The short hole diffusion length and/or passive layers formed on the pore walls are required for porosification of doped InP. The concentration of electrolyte can be increased to satisfy these conditions and can be used to achieve selective porosification of doped InP (see FIG. 6).

### Example 2: Reflectance Measurement of InP Multilayer Structure

### Materials and Methods

After the porosification of a multilayer structure of Example 1 at 1.5 V in 3.3M HCl, the etched structure's silicon dioxide layer was removed using a buffered oxide etch and then the reflectance of the nanoporosified InP multilayer structure was measured by a commercial Filmetrics F40 EXR capable of spot-measurement of thickness and optical properties of thin films within the spectral range of 400 and 1700 nm.

### Results

The refractive indices of nanoporous InP layers depends on their porosities and they could be as small as 1 if the porosity is 100% (i.e., the doped InP is electropolished entirely). These layers of alternating indices of refraction (between the high index of the undoped InP layer and lower index porosified or electropolished layers) can create successive constructive or destructive interferences. When the thicknesses of each layer corresponds to, respectively, ¼ of the optical wavelength, these stacks of alternating layers can act as a reflective mirror which could be used to achieve long wavelength emitting VCSELs.

FIG. 7 shows the measured reflectance of an InP/NP InP Distributed Bragg Reflector (DBR) having six pairs ¼ λ layers, where the reflectance of the InP multilayer structure, porosified at 1.5V in 3.3M HCl, was measured by a commercial Filmetrics F40 EXR capable of spot-measurement of thickness and optical properties of thin films within the spectral range of 400 and 1700 nm. Due to large refractive index contrast between the nanoporous InP layers (<1.7) and undoped InP layers (3.19), nearly 100% reflection with wide stopband centered at 1240 nm has been achieved. The center wavelength and stopband width of nanoporous InP DBRs can be simply adjusted by changing porosity and layer thicknesses.

### Example 3: Preparation and Testing of InP Multilayer Structures (Low Doping)

### Materials and Methods

Multilayer structures were formed from indium phosphide was homoepitaxially grown on single side polished n-InP substrate by MOCVD. Doped layers were doped with germanium dopant at the doping concentrations listed below. The multilayer structure contained alternating layers of n-doped (5×10¹⁸ cm⁻³) and undoped InP layers. A base layer was formed of an n-doped InP layer with a doping concentration of only 1×10¹⁷ to 1×10¹⁸ onto which a 300 nm layer of undoped InP was formed. A 140 nm n-doped InP layer was deposited onto the 300 nm layer. Then, a 110 nm layer of undoped InP was deposited onto the 140 nm layer. Additional layers of doped InP (140 nm; 5×10¹⁸ cm⁻³) and undoped InP (110 nm) were deposited. The final layer of InP was undoped. The structure is represented in FIG. 1 (see left). The final multilayer structure contained six doped InP layers (140 nm; 5×10¹⁸ cm⁻³) in between undoped InP layers. Then, a capping layer of silicon dioxide was deposited onto the entire multilayer structure and a side wall of the multilayer structure was exposed by removal of selected portion of the silicon dioxide layer by plasma-enhanced chemical vapor deposition and wafers are cleaved into narrow bars in order to expose the sidewalls of doped InP layers for electrochemical etching.

Subsequently, the multilayer structures were electrochemically (EC) etched in various concentrations of aqueous electrolytes (HBr, H₂SO₄, KOH, and HCl) and at different anodic voltages, according to the methods described above. The anodic voltages were applied for 5 min to 1 hour. The conditions tested and observed results are provided in Table 2 below.

TABLE 2

| Electrolyte | Anodic Voltage | Observations |
|---|---|---|
| 10% HBr | 1.3 V and 1.6 V | Doped InP has high porosity |
| | | (>70%) |
| 10% HBr | >1.7 V | Doped InP electropolished |
| 10% H₂SO₄ | >1.2 V | Doped InP has very high porosity |
| | | (>80%) polished |
| 6M KOH | >1.2 V | Slow etch rate (>10× slower than |
| | | etching in HCl) |
| 5% or 10% HCl | <1.6 V | Doped InP has high porosity |
| 5% or 10% HCl | 1.8 V | Doped InP has the lowest porosity |
| 5% or 10% HCl | >2.0 V | Doped InP has high porosity |
| 3% HCl | 1.6 V and 1.9 V | Doped InP has very high porosity |

### Results

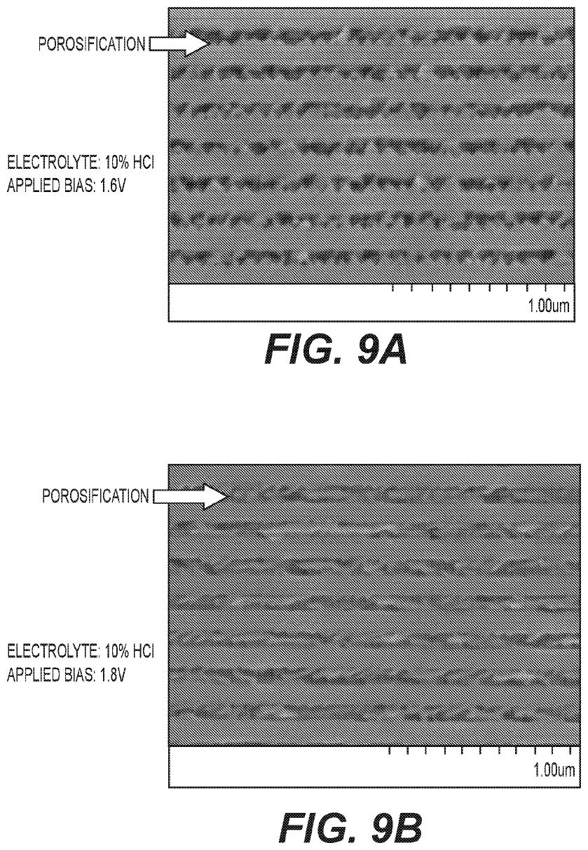

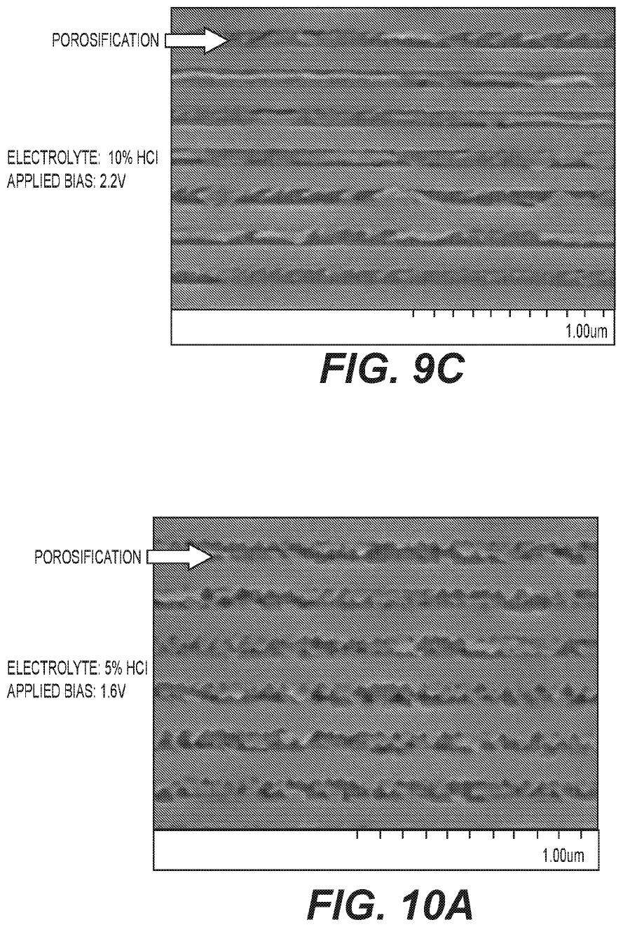

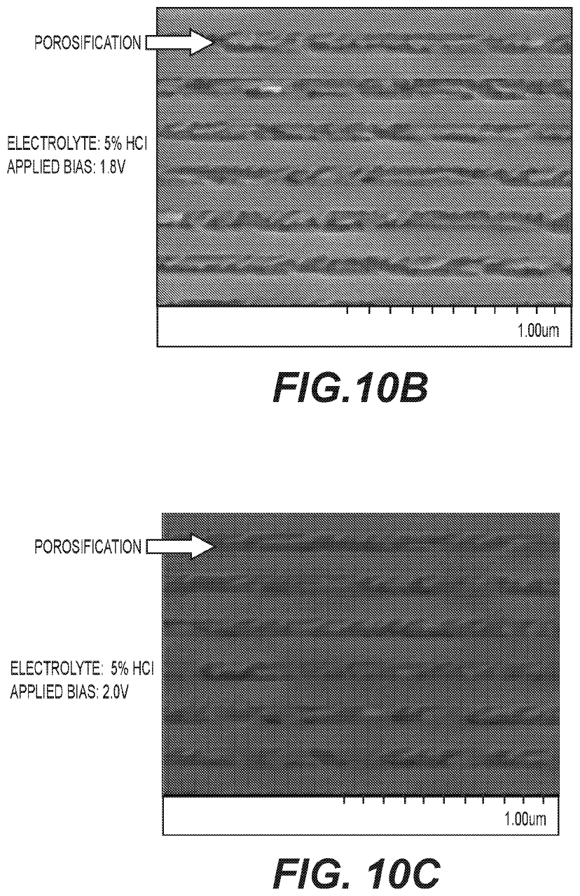

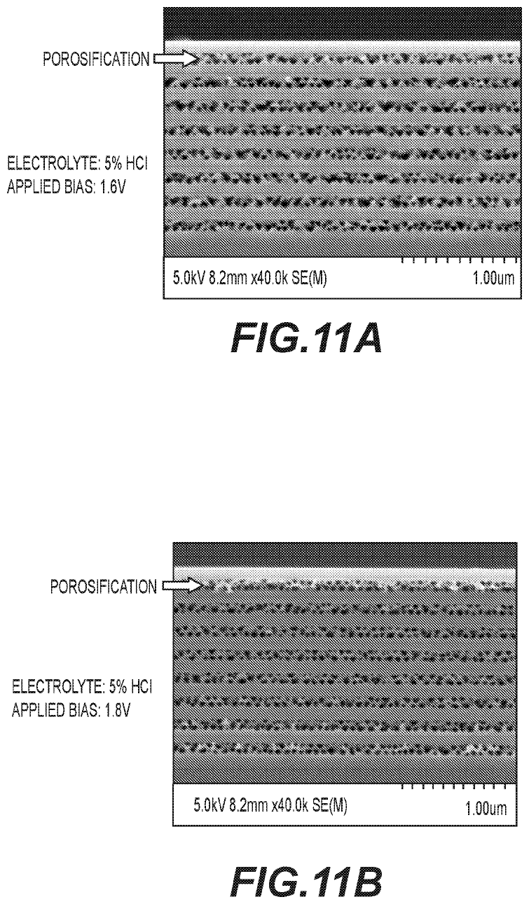

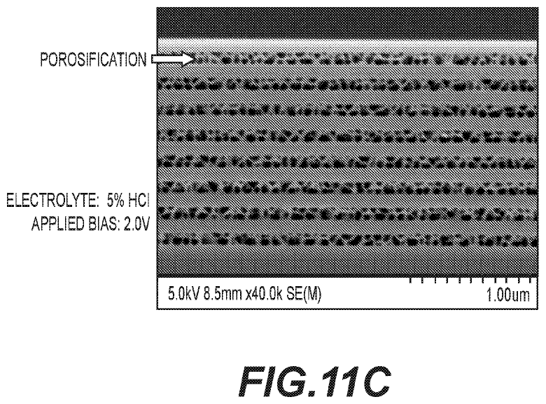

As shown in the observation in Table 2, doped layers that were porosified were found to be nanoporous after electrochemical etching. It was also found, that dependent on the EC conditions used, including the electrolyte choice, concentration thereof, and bias voltage applied, the doped InP layers could be either porosified or etched (electropolished) away. FIGS. 9A-C, 10A-C, and 11A-C show SEM images of doped layers in 10% HCl and 5% HCl electrolytes.

### Example 4: Reflectance Measurement of InP Multilayer Structure of Example 3

### Materials and Methods

The nanoporosified InP multilayer structure of Example 3 with a 5×10¹⁸ cm⁻³ doping concentration was porosified in 5% HCl electrolyte, at a 1.8V bias applied for 4 mins with Pt counterelectrode. Reflectance of the structure was measured by a commercial Filmetrics F40 EXR capable of spot-measurement of thickness and optical properties of thin films within the spectral range of 900 and 1800 nm. Additionally, the reflectance of a nanoporosified InP multilayer structure of Example 1, having a higher porosity, with a 2×10¹⁹ cm⁻³ doping concentration (porosified at 1.5 V for 15 minutes in 3.3M HCl) was also measured.

### Results

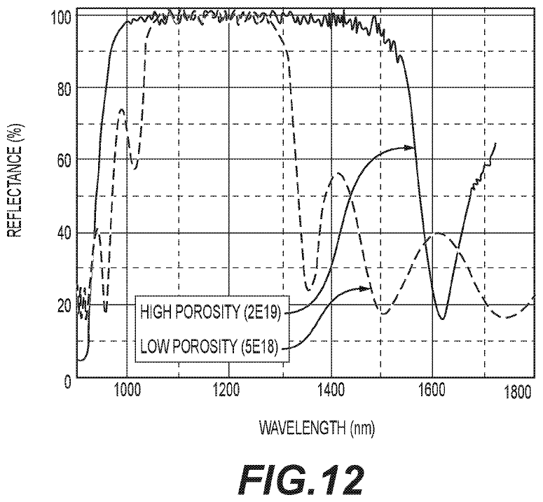

FIG. 12 shows the measured reflectance of two InP/NP InP Distributed Bragg Reflectors (DBRs) each having six pairs ¼ λ layers, where the reflectance of the InP multilayer structure, was measured by a commercial Filmetrics F40 EXR capable of spot-measurement of thickness and optical properties of thin films within the spectral range of 900 and 1800 nm. Due to large refractive index contrast between the nanoporous InP layers (<1.7) and undoped InP layers (3.19), nearly 100% reflection with wide stopband centered at 1250 nm has been achieved for sample with 2×10¹⁹ cm⁻³ doping concentration. The center wavelength and stopband width of the nanoporous InP DBRs can be simply adjusted by changing porosity, such as by way of doping concentration alone or in combination with other parameters (bias voltage applied, electrolyte and concentration thereof), and layer thicknesses.

### Example 5: Vertical Cavity with Bottom Nanoporous InP DBR Mirror

### Materials and Methods

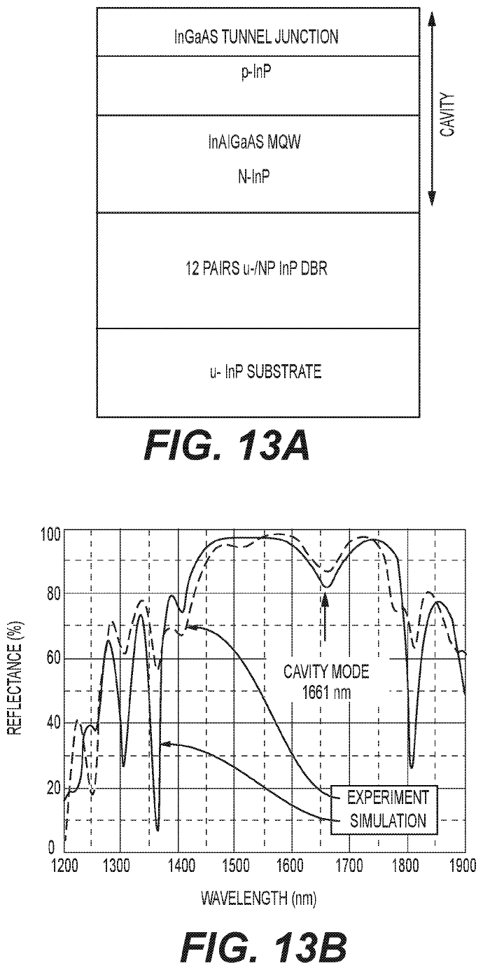

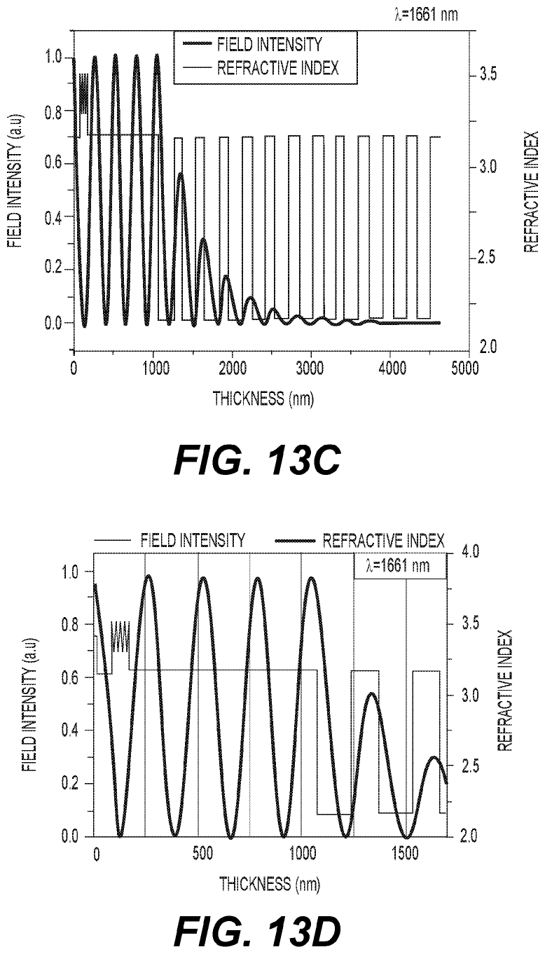

A vertical cavity using a nanoporous InP DBR structure, prepared according to Example 3 (8% HCl electrolyte, 1.8V bias applied for 4.5 mins with Pt counterelectrode), having twelve pairs ¼ λ layers as the bottom mirror on an undoped InP substrate was constructed. The vertical cavity portion of structure included a bottom layer of n-InP (about 930 nm), a layer of InAlGaAs multiple quantum wells (MQW) (81 nm), a layer of p-InP (71 nm), and a top layer InGaAs tunnel junction layer (20 nm). The complete vertical cavity structure including cavity and bottom DBR mirror is shown in FIG. 13A.

Reflectance measurements on the vertical cavity were performed using a Bruker Vertex 70+Hyperion 2000 within the spectral range of 900 and 1900 nm.

Lastly, an optical field simulation (%=1661 nm) was also performed using MATLAB software.

### Results

As shown in FIG. 13B, two dips (%=1405 and 1661 nm) were shown in the experimental reflectance spectrum. A simulation of the reflectance spectrum based on the structure in FIG. 13A demonstrated good agreement with the experiment result, which indicated the formation of a vertical cavity using NP InP DBR mirror at the bottom and the top semiconductor/air interface as a partial reflector mirror. From the reflectance simulation it was also possible to extract/simulate the optical field distribution showing the field intensity and refractive index as a function of thickness for the bottom DBR structure, as shown in FIGS. 13C and 13D. Further, for the optical field simulation: a clear standing wave at 1661 nm wavelength was shown in the cavity due to the presence of the nanoporous InP DBR mirror.

### Example 6: Vertical Cavity with Bottom Nanoporous InP DBR Mirror and Top Dielectric DBR Mirror

### Materials and Methods

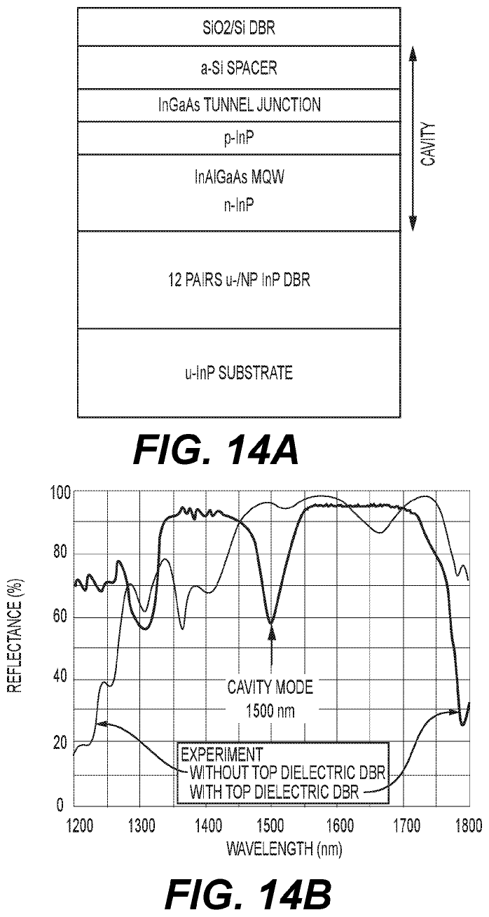

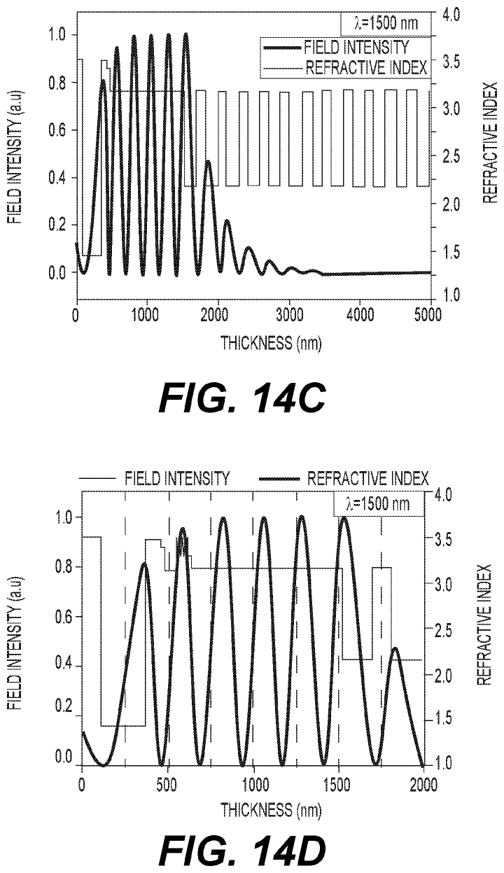

A vertical cavity using a nanoporous InP DBR structure, prepared according to Example 3 (8% HCl electrolyte, 1.8V bias applied for 4.5 mins with Pt counterelectrode), having twelve pairs ¼ λ layers as the bottom mirror on an undoped InP substrate was constructed. The vertical cavity portion of structure included a bottom layer of n-InP (about 930 nm), a layer of InAlGaAs MQW (81 nm), a layer of p-InP (71 nm), a layer InGaAs tunnel junction layer (20 nm), and an a-Si-spacer (100 nm). Finally, a top SiO₂ (252 nm)/a-Si (107 nm) DBR top mirror formed part of the structure. The complete vertical cavity structure including the cavity and top and bottom DBR mirrors described is shown in FIG. 14A.

Reflectance measurements on the vertical cavity were performed using a Bruker Vertex 70+Hyperion 2000 within the spectral range of 900 and 1900 nm.

Lastly, an optical field simulation (λ=1500 nm) was also performed using MATLAB software.

### Results

It is noted that the additional amorphous silicon (a-Si) layer was used in order to move the cavity mode to 1500 nm (see FIGS. 14A and 14B). As shown in FIG. 14B, a dip (λ=1500 nm) was shown in the experimental reflectance spectrum with the top SiO₂/a-Si DBR top mirror present. Two reflectance spectra were taken with and without an a-Si spacer and the top SiO₂/a-Si DBR top mirror, respectively. Due to higher reflectance with the SiO₂/a-Si dielectric top DBR mirror, as compared to the semiconductor/air interface, the dip was observed to become deeper. From the simulation, it was also possible to extract/simulate an optical field distribution showing the field intensity and refractive index as a function of thickness of the DBR structures present, as shown in FIGS. 13C and 13D, respectively. Further, for the optical field simulation: a clear standing wave for 1500 nm wavelength was shown in the cavity due to the presence of the nanoporous InP and dielectric silicon-based DBR mirrors present.

Unless defined otherwise, all technical and scientific terms used herein have the same meanings as commonly understood by one of skill in the art to which the disclosed invention belongs. Publications cited herein and the materials for which they are cited are specifically incorporated by reference.

Those skilled in the art will recognize, or be able to ascertain using no more than routine experimentation, many equivalents to the specific embodiments of the invention. Such equivalents are intended to be encompassed by the following claims.

1. A multilayer structure comprising:
a plurality of undoped or low n-doped indium phosphide or gallium arsenide layers present on an optional single-crystalline substrate formed of indium phosphide, gallium arsenide, sapphire, silicon, or silicon carbide,
wherein the multilayer structure comprises at least one layer of an n-doped indium phosphide or gallium arsenide which is present between at least two layers of undoped or low doped indium phosphide or gallium arsenide and the n-doped indium phosphide or gallium arsenide contains at least a region or portion that is porous or electropolished due to electrochemical etching, and
wherein the at least one layer of n-doped indium phosphide or gallium arsenide, when porous, comprises a plurality of pores within the n-doped indium phosphide or gallium arsenide layer that are confined by adjacent undoped or low n-doped indium phosphide or gallium arsenide layers that are non-porous or substantially non-porous.

2. The multilayer structure of claim 1, wherein the plurality of undoped or low doped indium phosphide or gallium arsenide layers are indium phosphide layers and the at least one layer of an n-doped indium phosphide or gallium arsenide is made of indium phosphide.

3. The multilayer structure of claim 1, wherein the plurality of undoped or low doped indium phosphide or gallium arsenide layers are gallium arsenide layers and the at least one layer of an n-doped indium phosphide or gallium arsenide is made of gallium arsenide.

4. The multilayer structure of claim 1, wherein the plurality of undoped or low doped indium phosphide or gallium arsenide layers are undoped.

5. The multilayer structure of claim 1, wherein the plurality of undoped or low doped indium phosphide or gallium arsenide layers are low n-doped having an n-dopant concentration at or below 1-50×10¹⁷ cm⁻³.

6. The multilayer structure of claim 1, wherein the at least one layer of n-doped indium phosphide or gallium arsenide has an n-dopant concentration of at least about 1×10¹⁹ cm⁻³; or in a range of between about 0.1 to 10×10¹⁹ cm⁻³ to 10×10²⁰ cm⁻³.

7. The multilayer structure of claim 1, wherein the at least one layer of n-doped indium phosphide or gallium arsenide, when porous, has a porosity of at least about 30%, 40%, 50%, 60%, 70%, 80%, or 90%.

8-11. (canceled)

12. The multilayer structure of claim 1, wherein a refractive index contrast (Δn) is present between the porous or electropolished at least one layer of n-doped indium phosphide and the undoped or low doped indium phosphide layers and is in a range of about 0.5 to about 2.

13-17. (canceled)

18. A method of making the multilayer structure of claim 1, the method comprising the steps of:
(a) forming a first layer of undoped or low doped indium phosphide or gallium arsenide above an optional substrate layer, if any;
(b) depositing a second layer of an n-doped indium phosphide or gallium arsenide over the first layer;
(c) depositing a third layer of undoped or low doped indium phosphide or gallium arsenide above the second layer;
(d) optionally repeating steps (b) and (c) to form additional alternating layers the n-doped indium phosphide or gallium arsenide and the undoped or low doped indium phosphide or gallium arsenide;
(e) depositing a capping layer over the entire multilayer structure;
(f) removing at least a portion of the capping layer to selectively expose at least one sidewall of the multilayer structure; and
(g) electrochemically (EC) etching n-doped indium phosphide or gallium arsenide layers in the presence of an electrolyte and under an applied bias voltage to selectively porosify or electropolish at least a portion of the n-doped indium phosphide or gallium arsenide layers present;
wherein the n-doped indium phosphide or gallium arsenide layers, when porosified, comprise a plurality of pores within the n-doped indium phosphide or gallium arsenide layer that are confined by adjacent undoped or low n-doped indium phosphide or gallium arsenide layers that are non-porous or substantially non-porous.

19. (canceled)

20. The method of claim 18, wherein the capping layer is made of silicon dioxide, silicon nitride (SiNₓ), hafnium oxide (HfO₂), or a photoresist material.

21. The method of claim 18, wherein the undoped or low doped indium phosphide or gallium arsenide layers present are indium phosphide layers and the n-doped indium phosphide or gallium arsenide layers present are made of indium phosphide.

22. The method of claim 18, wherein the undoped or low doped indium phosphide or gallium arsenide layers present are gallium arsenide layers and the n-doped indium phosphide or gallium arsenide layers present are made of gallium arsenide.

23. The method of claim 18, wherein the undoped or low doped indium phosphide or gallium arsenide layers present are undoped.

24. The method of claim 18, wherein the undoped or low doped indium phosphide or gallium arsenide layers present are low n-doped having an n-dopant concentration at or below 1-50×10¹⁷ cm⁻³.

25. The method of claim 18, wherein the n-doped indium phosphide or gallium arsenide layers present have an n-dopant concentration of at least about 1×10¹⁹ cm⁻³; or in a range of between about 0.1×10¹⁹ cm⁻³ to 10×10²⁰ cm⁻³.

26. The method of claim 18, wherein the n-doped indium phosphide or gallium arsenide layers present, when porosified, have a porosity of at least about 30%, 40%, 50%, 60%, 70%, 80%, or 90%.

27-29. (canceled)

30. The method of claim 18, wherein the n-doped indium phosphide or gallium arsenide layers present are doped with an n-type dopant selected from a Ge dopant, Si dopant, or combination thereof.

31. The method of claim 30, wherein the n-type dopant is obtained from a dopant source selected from silane (SiH₄), germane (GeH₄), isobutylgermane (IBGe), and combinations thereof.

32. (canceled)

33. The method of claim 18, wherein the electrolyte in step (g) comprises halide ions, hydrochloric acid (HCl), sulfuric acid (H₂SO₄), hydrofluoric acid (HF), KOH, NaOH, Ba(OH)₂, Ca(OH)₂, Sr(OH)₂, NH₄OH, NaCl, NaF, nitric acid (HNO₃), organic acids and their salts (such as oxalic acid and citric acid), and mixtures thereof.

34. (canceled)

35. The method of claim 18, wherein the applied bias voltage in step (g) is in a range of between about 0.1 to 10 V, 1.0 to 5V, or 1.0 to 2.5V and is applied for at least about 5 min, 10 min, 15 min, 20 min, 25 min, 30 min, 35 min, 40 min, 45 min, 50 min, 55 min, 60 min, 2 hours, 3 hours, 4 hours, 5 hours, 6 hours, 10, hours, 15 hours, 20 hours, or 24 hours.

36. (canceled)

37. A device comprising the multilayer architecture structure of claim 1.

38. The device of claim 37, wherein the device is selected from the group consisting of light-emitting diodes, field-effect transistors, laser, laser diodes, and biomedical devices.

39. The device of claim 38, wherein the laser diode is a vertical cavity surface emitting laser (VCSEL) and the multilayer structure is a distributed Bragg reflector in the vertical cavity surface emitting laser (VCSEL).

40. (canceled)

41. The device of claim 39, wherein the vertical cavity surface-emitting laser (VCSEL) emits in the near infrared wavelength range and/or the infrared wavelength range.
